(19) United States
(12) Patent Application Publication
(10) Pub. No.: US 2022/0230587 A1
(43) Pub. Date: Jul. 21, 2022

(54) OPTO-ELECTRONIC DEVICE FABRICATION METHOD AND ELECTRONIC CIRCUIT

(71) Applicants: Qing LI, Waterloo (CA); Manoj SACHDEV, Waterloo (CA); William WONG, Waterloo (CA); Mohsen ASAD, Waterloo (CA)

(72) Inventors: Qing LI, Waterloo (CA); Manoj SACHDEV, Waterloo (CA); William WONG, Waterloo (CA); Mohsen ASAD, Waterloo (CA)

(21) Appl. No.: 17/613,323

(22) PCT Filed: Jun. 25, 2019
(86) PCT No.: PCT/CA2019/050879

§ 371 Date: Nov. 22, 2021

Related U.S. Application Data
(60) Provisional application No. 62/854,109, filed on May 29, 2019.

(51) Int. Cl. G09G 3/3233; H01L 33/00; H01L 33/06; H01L 33/12; H01L 33/50

(52) U.S. Cl. CPC G09G 3/3233; H01L 33/0093; H01L 33/06; H01L 33/12; H01L 2933/0041; G09G 2300/0842; G09G 2320/0209; G09G 2330/021; H01L 33/50

(57) ABSTRACT

An electronic circuit for thin-film transistors, the circuit including: a driving TFT; an input signal; a compensation TFT provided between gate and source terminals of the driving TFT; a storage TFT provided between the input signal and the gate of the driving TFT; a plurality of switching TFTs configured to charge the storage TFT from the input signal in one cycle and then charge the compensation TFT from the storage TFT during another cycle, such that the compensation TFT compensates for degradation of the driving TFT. An opto-electronic fabrication method including: forming an opto-electronic device on a growth substrate; temporarily bonding the opto-electronic device to a carrier substrate; removal of the growth substrate; etching the opto-electronic device to a predetermined height; coating the opto-electronic device with a functional metal layer; bonding the opto-electronic device onto a final receiver substrate; and removing the carrier substrate.

### FIELD

The present disclosure relates generally to an opto-electronic device fabrication method and to an electronic circuit adaptable to transistor degradation. More particularly, the present disclosure relates to an opto-electronic device fabrication method and an electronic circuit that adapts to degradation, which can be used together with the opto-electronic device fabrication method to provide flexible thin-film pixel circuits.

### BACKGROUND

In electronics, thinner, improved displays are moving toward generally larger, flexible displays. In order to achieve this goal, one of the main challenges is the reliability of thin-film-transistor (TFT) based pixel circuits on the backplane of a display. TFT pixel circuits need to function reliably under both flat and bending conditions. Further, in order to produce TFT pixel circuits more efficiently, improved integrated circuit fabrication methods are required.

Conventional technologies such as CMOS are generally too expensive for large display applications. Further, flexible displays typically require low-temperature fabrication and, as such, CMOS or similar technologies are generally not suitable.

There are various types of thin-film transistors (TFT). For example, p-channel devices are usually made from polymer/organic TFTs, and n-channel devices are usually made from, for example, hydrogenated amorphous silicon (a-Si:H) and transition-metal oxide (TMO) TFTs, such as, for example, InGaZnO (IGZO) TFTs. Polycrystalline silicon (poly-Si) TFTs are an exception in that poly-Si can be used to implement ambipolar transistors. However, in poly-Si transistors, performance non-uniformity can be a drawback due to grain boundary defects. Ambipolar circuits may also include high off currents so the switching action does not turn off completely and poor uniformity across large areas that may degrade image quality for large screens.

Amorphous silicon (a-Si:H) technology used for traditional LCD displays has an edge in terms of low-cost large-area fabrication, excellent device uniformity as well as bendability. However, a-Si:H TFTs can exhibit much larger threshold-voltage (V_{T}) degradation over-time compared to CMOS owing to defects and dangling bonds in its disordered structure. A sustained positive (or negative) gate voltage stress can change the value of V_{T} to be higher (or lower). Consequently, if TFTs are used for controlling current through LEDs, the current degrades over-time. TFT based pixel circuits often exploit various circuit techniques to compensate such change in current. In addition, flexible displays also exhibit change in the current in TFTs as a function of bending stress.

Various solutions have been proposed for the degradation problem of a-Si TFTs. Some examples include:

(a) Reverse annealing the TFT with a negative voltage to recover a certain portion of the degraded output current. This approach has a disadvantage in that there is limited compensation capability and the control signals are complex to implement. This approach also reduces the emission time in each display cycle. It also requires generation and application of negative voltage, which can be difficult to implement.

(b) External detection of the degradation of the output TFT with a feedback to modulate the data voltage to obtain the correct output current. This approach has a disadvantage in that it can require complex external detection circuits and the speed of operation may also be affected due to sensing and feedback loop delay. Furthermore, the dynamic range of the display may also be affected.

(c) Charge-transfer method with 4-TFT implementation based on correlation between two TFTs in linear and saturation modes. This approach has a disadvantage in that it does not fully resolve the threshold-voltage degradation issue. There is still a small portion of uncompensated output current due to the nature of the circuit operation. Also, the charge-injection on the access TFT may reduce dynamic range in the driving phase. Moreover, three distinct control signals are complex to generate from an external timing circuit.

Further, when it comes to fabricating opto-electronics, there can be issues such as:

(a) Thinning the LEDs after bonding the p-side onto a receiver substrate and etching the n-side with electrochemical process. This approach has a disadvantage that the LEDs are flip-chip bonded onto a substrate and the active region that produces the light is not near the surface. In addition, most of the reflective metals make a poor ohmic contact with p-GaN. As a result, there is a contradiction between having a highly reflective layer and a good ohmic contact.

(b) Stack LEDs for transferring from different substrates onto a receiver substrate by using a planarization process and open via through the layers. This approach has a disadvantage in that the process includes several planarization and via opening steps, which can increase the error because of misalignment during lithography.

As such, there is a need for an improved method of fabricating integrated circuits and, in particular, flexible, thin-film pixel circuits as well as improved electronic circuits for controlling degradation of transistors, particularly in thin-film pixel circuits.

### SUMMARY

According to an aspect herein, there is provided an electronic circuit for thin-film transistor degradation compensation, the circuit including: a driving TFT that supplies current from a driving source to a load; an input signal; a compensation TFT, configured as a capacitor, that is provided between gate and source terminals of the driving TFT; a storage TFT, configured as a capacitor provided between the input signal and the gate of the driving TFT; a plurality of switching TFTs configured to charge the storage TFT from the input signal in a predetermined cycle and then charge the compensation TFT from the storage TFT during a different predetermined cycle, such that the compensation TFT compensates for degradation of the driving TFT. In some cases, the plurality of switching TFTs comprises a maximum of three TFTs, which are configured such that there are a maximum of two control signals.

According to an aspect herein, there is provided an electronic circuit for thin-film transistor degradation compensation, the circuit including: a driving TFT that selectively supplies current from a driving source to a load; a compensation TFT, configured as a capacitor, that is provided between gate and source terminals of the driving TFT; a storage TFT, configured as a capacitor; a plurality of switching TFTs, configured to act as switches; two control signals, including a row-select signal and a boosting signal; an input signal; wherein, when the row-select signal is on and the boosting signal is off, the plurality of switches are set such that charge flows from the input signal to the storage TFT and when the row-select signal is off and the boosting signal is on, the plurality of switches are set such that charge flows from the storage TFT to the compensation TFT and a gate of the driving TFT, such that the compensation TFT compensates for degradation of the driving TFT.

In some cases, the geometry of the driving and compensation TFTs may be configured to balance charge components in the emitting phase.

In some cases, the geometry of the driving and compensation TFTs may be configured based on bending forces on the driving and compensation TFTs.

In some cases, the plurality of switching TFTs may be configured to isolate the compensation TFT and the gate of the driving TFT from interference of the input signal.

In some cases, the plurality of switching TFTs may be configured to allow acquisition of the input signal with reduced or without cross-talk to neighboring pixels.

In some cases, the plurality of switching TFTs includes a maximum of 3 TFTs.

According to another aspect herein, there is provided an opto-electronic fabrication method including: forming at least one opto-electronic device on a growth substrate, wherein the opto-electronic device includes a buffer layer and an epitaxial layer; temporarily bonding the at least one opto-electronic device to a carrier substrate via a bonding material; removal of the growth substrate; etching at least the buffer layer to bring the at least one opto-electronic device to a predetermined height from the carrier substrate; etching the carrier bonding material away from edges of the at least one opto-electronic device; coating the at least one opto-electronic device with a functional metal layer; bonding the at least one opto-electronic device onto a final receiver substrate; and removing the carrier substrate.

In some cases, the epitaxial layer may include a p-doped layer, an active layer including quantum wells, and a highly doped layer.

In some cases, the bonding material may also surround and support the at least one opto-electronic device.

In some cases, the etching at least a buffer layer may further include etching a predetermined portion of the highly doped layer.

In some cases, the etching at least the buffer layer to a predetermined height may be selected to maximize the out-coupling of light from the opto-electronic device.

In some cases, the final receiver substrate may include at least one driving circuit for the at least one opto-electronic device.

In some cases, the method further includes repeating the method to the coating the at least one opto-electronic device with a functional metal layer for a plurality of opto-electronic devices, each opto-electronic device having a different predetermined height and then repeating the bonding the at least one opto-electronic device onto a final receiver substrate for each of the plurality of opto-electronic devices from shorter predetermined height to taller predetermined height.

In some cases, the bonding the at least one opto-electronic device onto the final receiver substrate may include bonding using an inert metal on the receiver substrate and a bonding agent metal on the at least one opto-electronic device and bringing the inert metal into contact with the bonding agent metal.

According to another aspect herein, there is provided an opto-electronic fabrication method including: forming at least one opto-electronic device on a growth substrate; adding a bonding/structural material around the at least one opto-electronic device to form an opto-electronic matte; temporarily bonding the opto-electronic matte to a carrier substrate; removal of the growth substrate; and removal of the carrier substrate.

In some cases, the method may further include forming a light conversion layer onto the opto-electronic matte as a part of the opto-electronic matte. The formation of the light conversion layer onto the opto-electronic matte may be performed prior to temporarily bonding the opto-electronic matte to a carrier substrate or after removal of the carrier substrate and as a part of further processing.

### BRIEF DESCRIPTION OF THE FIGURES

Other aspects and features of the present disclosure will become apparent to those ordinarily skilled in the art upon review of the following description of specific embodiments in conjunction with the accompanying figures.

Embodiments of the present disclosure will now be described, by way of example only, with reference to the attached Figures.

FIG. 1 is a schematic of a pixel circuit according to an embodiment herein together with a timing diagram;

FIG. 2A is a schematic of the pixel circuit of FIG. 1 during the programming phase;

FIG. 2B is a schematic of the pixel circuit of FIG. 1 during the emitting phase;

FIG. 3 shows graphs illustrating the performance of the pixel circuit of FIG. 1 on a flexible substrate with tensile/compressive bending applied over a typical data range

FIG. 4 is a schematic of the channel and overlap capacitances that share charge in the pixel circuit of FIG. 1 during the emitting phase.

FIG. 5A shows the cross-section schematic of a fabricated a-Si:H TFT.

FIG. 5B shows the normalized drain-source current (I_{DS}) vs gate-source voltage (V_{GS}) curves of the fabricated a-Si:H TFT (W/L=100 μm/20 μm) in linear and saturation modes when laid flat,

FIG. 5C shows the schematic of various mechanical strain conditions applied to the fabricated a-Si:H TFT.

FIG. 6 shows the normalized I_{DS} of a TFT (W/L=100 μm/20 μm) under linear (LIN) and saturation (SAT) voltage-bias stress conditions for three hours when a) laid flat (b) under tensile strain and (c) under compressive strain. The bending experiments contain both configurations where the applied strain was parallel (//) and perpendicular (⊥) to L.

FIG. 7A shows a micro-graph of an exemplary pixel circuit.

FIG. 7B shows the bending test setup with tensile strain.

FIG. 7C shows the bending test setup with compressive strain.

FIG. 7D shows the micro-controller and external IC components for control-signal generation and data logging.

FIG. 8 shows the measured transient waveforms of (a) the input signals. (b) the output current of the 6T pixel circuit at the initial time before bias stress, and (c) The output current after 24 hours of bias stress test with maximum V_{data} when the pixel was laid flat, and under tensile and compressive strains.

FIG. 9 shows the C-V curves of the correlating TFTs (a) T2 and (b) T0 measured initially and after long-term (24 hours) bias-stress test. □, X, and Δ symbols depict flat, tensile, and compressive strain conditions, respectively, after 24 hours. ∘ symbols depict initial conditions.

FIG. 10 shows the normalized output current of the 6T pixel circuit for the entire Vdata range after bias-stressed for 24 hours under flat (□), tensile strain (λ), and compressive strain (X) conditions along with the 2T uncompensated pixel circuit under flat conditions (♦).

FIG. 11. Shows the simulation of normalized output current of the 6T pixel circuit (□) and 2T uncompensated pixel circuit (Δ) with increasing ΔV_{T,0} under flat conditions at maximum V_{data}=15 V.

FIG. 12 illustrates heterostructure of an LED device on a substrate;

FIG. 13 illustrates LED device formation after etching and passivation;

FIG. 14 illustrates temporary bonding onto a receiver substrate;

FIG. 15 illustrates the removal of the growth substrate;

FIG. 16 illustrates the selective etching the backside of the LED device;

FIG. 17 illustrates the etching of the temporary bonding material;

FIG. 18 illustrates the coating of functional metal layers on the pixels;

FIG. 19 illustrates the bonding of the pixels/devices onto the final receiver substrate;

FIG. 20 illustrates the removal of the carrier/receiver substrate;

FIG. 21 illustrates the removal of the temporary bonding material; and

FIGS. 22A-C illustrate the formation of devices/pixels having various heights;

FIGS. 23A-C illustrate devices/pixels having various heights before transfer to a final receiver substrate;

FIG. 24 illustrates sequential bonding of devices/pixels of various heights onto a final receiver substrate;

FIG. 25 illustrates how light generated will be reflected toward each device's topside;

FIG. 26 illustrates optimized waveguide height;

FIG. 27 illustrates a depletion layer at the sidewall of devices/pixels;

FIG. 28 illustrates the formation of an opto-electronic matte (LED matte);

FIG. 29 illustrates the placement of an opto-electronic matte onto a backplane;

FIG. 30 illustrates further processing of an opto-electronic matte following placement onto a backplane;

FIG. 31 illustrates formation of a light conversion layer on an opto-electronic matte following placement on a backplane;

FIG. 32 illustrates formation of a light conversion layer on an opto-electronic matte while the opto-electronic matte is still on the growth substrate;

FIG. 33 illustrates transfer of the opto-electronic matte (including light conversion layer) onto a handle/carrier substrate; and

FIG. 34 illustrates placement of the opto-electronic matte (including light conversion layer) onto a backplane.

### DETAILED DESCRIPTION

The present disclosure generally describes embodiments of a method for fabricating opto-electronic circuits and, in particular, pixel circuits, as well as an improved pixel circuit for adapting to pixel degradation. The method for fabrication can provide for the mass-transfer of optoelectronic devices onto a secondary substrate that may contain driving circuits (for example, based on thin film transistors (TFTs), CMOS technology or the like) or other optical and mechanical components.

Embodiments of the proposed pixel circuit use an improved charge-transfer method to compensate for degradation of the driving TFT in order to provide a more uniform output over a longer period of time.

Embodiments of the method for fabrication are intended to enable improved circuits. In particular, to fabricate LED or micro-LED displays (both referred to as LEDs), it is required to transfer LEDs from a growth substrate (normally Sapphire or the like but may also be Si or the like) onto a substrate with active or passive driving circuits. Because of different coefficients of thermal expansion (CTE), direct bonding of devices from sapphire can be difficult. In embodiments herein, optical devices are transferred onto an intermediate substrate with a CTE close to that of the final receiver substrate. This enables transfer of optical devices onto a receiver substrate by using a bonding process at either low or high temperatures.

In addition, in conventional methods of growing epi layers on a heterogeneous substrate (such as Si or sapphire), the process typically starts with a high-resistive, high-defective buffer layer to stop threading defects towards the active quantum wells. The defects may can cause a higher voltage-drop in the resistive part of the device and result in lower efficiency. Currently, the etching of a buffer layer is typically performed after a single bonding and transfer of the optical devices onto a receiver substrate. However, this technique flips the device orientation with the active region oriented in the opposite direction, which is generally not optimized for light extraction efficiency. To boost the light extraction efficiency and remove the resistive part of optoelectronic devices, the device backside is typically etched either by wet or dry processes until a desired thickness. In embodiments of the method herein, the etching step can be performed when the devices are transferred onto the intermediate substrate and the backside is exposed.

Moreover, in conventional fabrication, the light emitted from the optical devices is generally not directional, and photons will emit in a large divergence angle, which can cause crosstalk between two adjacent pixels. Embodiments herein are intended to overcome this issue by coating the sidewalls of the optical devices with a reflective metallic layer. In embodiments of the method herein, both backside and sidewall of the LEDs are covered with a reflective metallic layer, which boosts both the light extraction efficiency and the directional emission.

With embodiments of the LED fabrication and bonding process herein, the n-side of the LED can be connected to the drain of the emitting TFT. In this configuration, the input data voltage to the pixel can be reduced by roughly the on-voltage of the LED. Thus, the power consumption during the operation of the pixel can be reduced. Also, with the thinning process of the LED, light extraction is improved, so the power required to deliver the same brightness is reduced. Therefore, the pixels in the display panel can be more energy efficient.

The first part of this disclosure will relate to embodiments of the proposed pixel circuit. Based on a ratio of TFT degradation in linear and saturation modes, a 6T pixel circuit is proposed to mitigate the impact of electrical instability of flexible a-Si:H TFTs. The circuit is intended to provide enhanced compensation performance through a self-compensating charge-transfer process. In addition, special consideration to the layout of TFTs has been given to allow adaptation of the pixel circuit under different bending conditions. Furthermore, only a two input signals are needed to control a row of such pixels, which reduces the complexity of external row drivers compared with previous solutions.

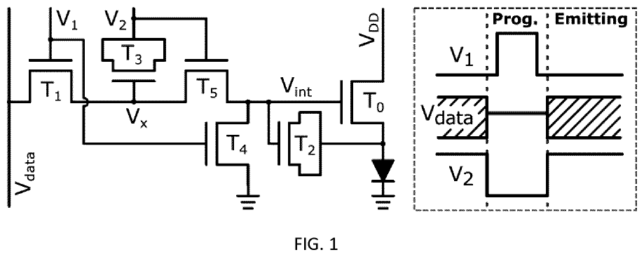

FIG. 1 is a schematic of an embodiment of a pixel circuit, in this case a 6-TFT (6T) pixel circuit, which uses an improved charge-transfer method to compensate for the degradation of the driving TFT (T₀).

T₀ is the driving TFT that supplies current to the LED. The compensation TFT (T₂), which has its source and drain shorted to form a metal-insulator-semiconductor (MIS) capacitor, is connected between the gate and source terminals of T₀ electrically and provides compensation during the charge transfer process. Another MIS capacitor (T₃) is used to store data prior to the emitting phase. The remaining TFTs (T₁, T₄, and T₅) are designed to act as switches. The control signal V₁ is the row-select signal and the boosting signal V₂ is the boosting signal. The operation of the pixel circuit is divided into two phases: programming and emitting.

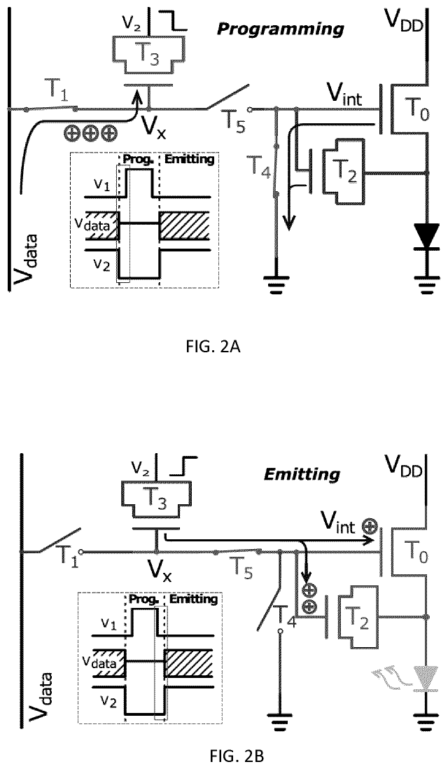

FIG. 2A illustrates the circuit in the programming phase. In the programming phase, V₂ is changed from high to low and subsequently control signal V₁ is set to high, such that T₅ is OPEN and then switches T₁ and T₄ are CLOSED. The charge on the internal node of the pixel circuit (Vᵢₙₜ) from the previous display cycle is drained to ground through T₄, while the storage capacitor T₃ is charged to the desired data voltage through T₁. In this phase, the brightness of the LED resets and the new data information is acquired. Both operations are carried out simultaneously without contaminating each other.

More particularly, in the programming phase, control signal V₂ is set to low first so that T₅ is in high impedance mode which isolates the internal node Vᵢₙₜ from the toggling V_{data}. At the same time, the gate voltage (Vₓ) of the storage capacitor T₃ is reduced and waiting for the new V_{data}. After a short delay, V₁ is set to high such that T₁ and T₄ are conducting. As a result, Vᵢₙₜ node is drained through T₄ to clear the brightness level of the previous display cycle. When Vᵢₙₜ reaches zero, T₀ is shut off and no current is flowing through LED. Then, there will be no residual luminescence impact from the previous display cycle. Meanwhile, T₃ has acquired charge based on the new V_{data} value through T₁. In this phase, the reset of previous state and the acquisition of the new data are carried out without cross-talk to neighboring pixels and power/ground rails.

FIG. 2B illustrates the circuit in the emitting phase. In the emitting phase, control signals V₁ and V₂ switch polarity sequentially, so that T₁ and T₄ become OPEN while T₅ is CLOSED. As a result, the internal node (Vᵢₙₜ) is isolated from the influence of the toggling V_{data} signal and ground. Then, at least part of the stored charge on T₃ (node Vₓ) is transferred to the node Vᵢₙₜ (gates of T₀) which determines the output current level to the LED, and the remaining charge is transferred to T₂ to provide ΔV_{T} compensation.

More particularly, after the programming phase ends, the pixel enters the emitting phase by switching the polarity of control signals V₁ and V₂ sequentially. This operation makes T₁ and T₄ in high impedance mode and T₅ conducting. Consequently, Vᵢₙₜ is isolated from the interference of the toggling V_{data} signal and ground. Then, the majority of the charge on T₃ is injected to Vᵢₙₜ and is stored on T₂, while a small portion is shared among parasitic capacitances of other TFTs.

With this configuration, bending of the circuit board becomes less of an issue. The correlating transistors T₀ and T₂ are oriented the same way on the layout so that any applied mechanical strain (such as bending) will have the same effect on them. Therefore, voltage compensation can be maintained, even during bending, or compensation may be enhanced. In other embodiments, the orientation of the transistors may be configured to take advantage of the higher degradation of, for example, T₂ during bending. For example, in some cases, the TFTs more be oriented 90 degrees from each other with, for example, T₂ having a channel length parallel to the bending direction and T₀ having a channel length orthogonal to the bending. For small strains, the orthogonally oriented TFT will generally have an over-compensation effect on the normalized drive current. As the bending increases, this over-compensation effect is reduced but compensation still occurs compared to no compensation at all.

This circuit configuration also has benefits when the LED is connected to the drain of T₀. When the LED is connected to the drain of T₀ the operation of the circuit is not affected, and the compensation remains effective. In addition, the data voltage swing can be reduced by the on-voltage of the LED. Thus, the pixel circuit can operate more efficiently.

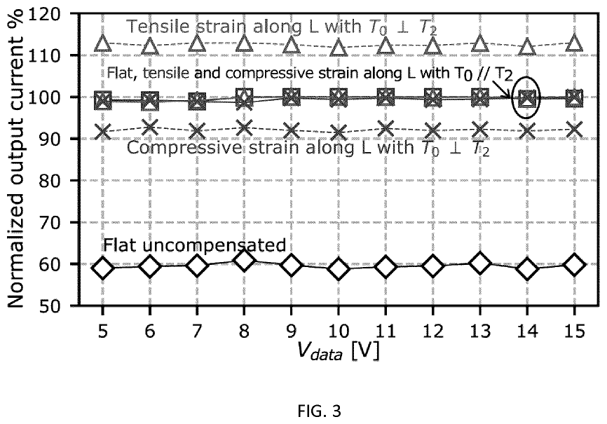

FIG. 3 shows the performance of the 6T pixel circuit on a flexible substrate with tensile/compressive bending applied over a typical data range. In experiments, the 6T pixel circuit can achieve near 100±3% output current retention for the entire V_{data} range under flat or bending conditions through the charge-transfer method and the orientation of the TFTs. Also, the circuit has a simple control scheme, using only two inverting input control signals, and is intended to allow the integration of the pixel onto a variety of display size panels.

The following description is intended to explain the charge-transfer self-compensating mechanism in further detail. Generally speaking, the self-compensating charge-transfer mechanism of the proposed 6T pixel circuit is governed by balancing charge components and utilizing the ΔV_{T} ratio between T₂ and T₀. In the following analysis, the LED is neglected to ease the calculation because the LED has negligible impact on compensation capability. The derivation is to demonstrate that under the same V_{data} voltage, the pixel circuit provides a constant current to the LED in spite of increasing ΔV_{T,0} conditions. Since the LED only glows in the emitting phase, charge equations are based on transistor behaviors in this phase.

In the emitting phase, T₂ is operating in linear mode and T₀ in saturation mode, so that before any long-term voltage-bias stress (ΔV_{T} has not occurred), the initial charge in the channel of T₂ and T₀ is expressed as:

Q_{ch,2}^{initial}=C_{ch,2}×(Vᵢₙₜ^{initial}−V_{T,2}) (1)

Q_{ch,0}^{initial}=⅔C_{ch,0}×(Vᵢₙₜ^{initial}−V_{T,0}) (2)

In the above Eqs., Q_{ch,2}^{initial} and Q_{ch,0}^{initial} are the total charge in the channel of T₂ and T₀ at their initial state, respectively. C_{ch,2} and C_{ch,0} are the channel capacitance of these two TFTs. The applied gate-source voltage and initial threshold voltages are expressed as Vᵢₙₜ^{initial} and V_{T,2}, V_{T,0}, respectively. After the pixel circuit has been operated under voltage-bias stress, both T₂ and T₀ are generally degrading due to the disordered nature of the amorphous material. Consequently, the degradation causes ΔV_{T} on both T₂ and T₀. After biased-induced stress, the resulting new channel charge Eqs. become:

Q_{ch,2}^{stressed}=C_{ch,2}×(Vᵢₙₜ^{stressed}−V_{T,2}−ΔV_{T,2}) (3)

Q_{ch,0}^{stressed}=⅔C_{ch,0}×(Vᵢₙₜ^{stressed}−V_{T,0}−ΔV_{T,0}) (4)

The degradation of T₂ and T₀ still follows the correlation rule, where the degradation of a TFT in linear mode is 1.5 times faster than saturation mode when the gate bias voltage is the same. The correlation is expressed as:

ΔV_{T,2}=3/2ΔV_{T,0} (5)

To achieve the self-compensating mechanism, Vᵢₙₜ^{stressed} should rise by the amount of ΔV_{T,0} from Vᵢₙₜ^{initial} automatically in the emitting phase. This relationship is expressed as:

Vᵢₙₜ^{stressed}=Vᵢₙₜ^{initial}+ΔV_{T,0} (6)

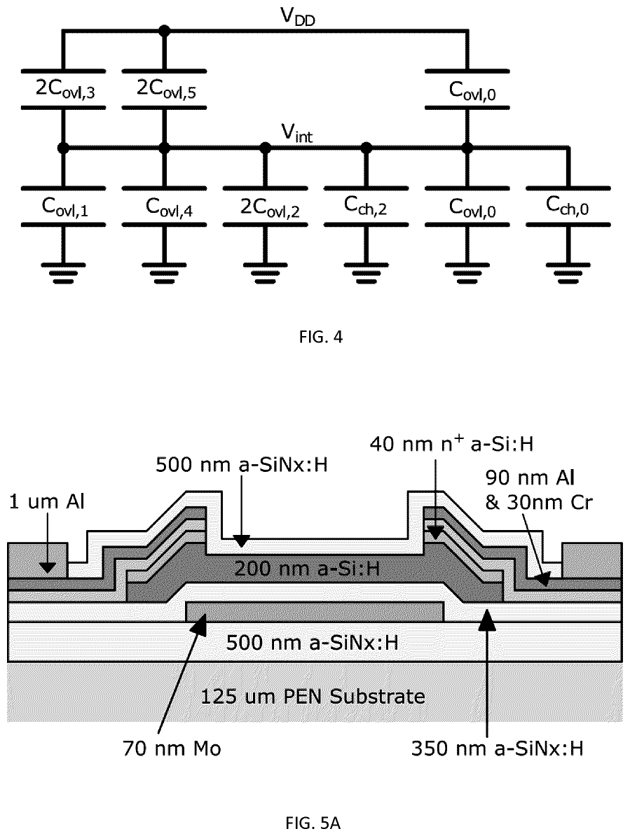

In order to realize the above relationship, the geometry of all TFTs should be designed correctly by balancing charge components in the emitting phase. As a result, the overlap capacitance that affects Vᵢₙₜ node should also be taken into account. The capacitor network in the emitting phase is shown in FIG. 4. It is assumed that the on-state of signal V₂ is equal to the supply voltage V_{DD}. The channel capacitance of T₅ is also neglected because T₅'s channel length can be designed as minimum size to allow a fast charge-transfer from the programming to the emitting phase.

The overlap capacitances between V_{DD} and Vᵢₙₜ (C_{ovl,top}) from FIG. 4 are expressed as:

C_{ovl,top}=C_{ovl,0}+2C_{ovl,3}+2C_{ovl,5} (7)

In addition, all the overlap capacitances between Vᵢₙₜ and ground (C_{ovl,bottom}) from FIG. 4 are expressed as:

C_{ovl,bottom}=C_{ovl,0}+C_{ovl,1}+2C_{ovl,2}+C_{ovl,4} (8)

According to the law of charge conservation, the charge in the capacitor network is expressed as:

C_{ovl,top}×(V_{DD}−Vᵢₙₜ)=C_{ovl,bottom}×Vᵢₙₜ+Q_{ch,2}+Q_{ch,0} (9)

C_{ovl,top}×V_{DD}=((C_{ovl,top}+C_{ovl,bottom})×Vᵢₙₜ+Q_{ch,2}+Q_{ch,0} (10)

It is assumed that only the channel capacitances are affected by the threshold voltage but not the overlap. Also, due to the close proximity of T₂ and T₀ on the layout, their initial threshold voltages V_{T,2} and V_{T,0} are assumed equal. After substituting Eqs. (1) and (2) into in Eq. (10), the initial charge balance before any bias-stress can be expressed as:

C_{ovl,top}×V_{DD}=(C_{ovl,top}+C_{ovl,bottom})×Vᵢₙₜ^{initial}+C_{ch,2}×(Vᵢₙₜ^{initial}−V_{T,0})+⅔C_{ch,0}×(Vᵢₙₜ^{initial}−V_{T,0}) (11)

After substituting Eqs. (3), (4), and (5) into Eq. (10), the charge-balance Eq. after the bias-stress of the pixel circuit, becomes:

C_{ovl,top}×V_{DD}=(C_{ovl,top}+C_{ovl,bottom})×Vᵢₙₜ^{stressed}+C_{ch,2}×(Vᵢₙₜ^{stressed}−V_{T,0}−3/2ΔV_{T,0})+⅔C_{ch,0}×(Vᵢₙₜ^{stressed}−V_{T,0}−ΔV_{T,0}) (12)

A new relationship after substituting Eqs. (11) and (12) into Eq. (6), is then obtained, which describes the relationship between capacitors as:

½C_{ch,2}=C_{ovl,top}+C_{ovl,bottom} (13)

½C_{ch,2}=2C_{ovl,0}+C_{ovl,1}+2C_{ovl,2}+2C_{ovl,3}+C_{ovl,4}+2C_{ovl,5} (14)

Here, Eq. (14) indicates that the geometry of the compensating TFT (T₂) is determined by the sum of overlap capacitances in TFTs (T₀, T₁, T₂, T₃, T₄, and T₅). Then, the capacitance values are substituted by the widths and lengths of relevant TFTs. In addition, the process parameters including the unit-square sheet capacitance of the channel (C_{ch}) and the overlap capacitance (Cₒᵥₗ) are inserted in the Eq. (14). Lastly, the minimum overlap length Lₒᵥₗ is generally dictated by the fabrication process. The relationship of capacitances shown in Eq. (14) is expressed as the channel width and length (W and L) of TFTs. The simplified Eq. (15) below serves the purpose to determine the sizes of TFTs in the 6T pixel circuit.

$${W}_{2} = \frac{2 {C}_{o v l} {L}_{o v l} ( 2 {W}_{0} + {W}_{1} + 2 {W}_{3} + {W}_{4} + 2 {W}_{5} )}{{C}_{c h} {L}_{2} - 4 {C}_{o v l} {L}_{o v l}} \qquad ( 15 )$$

The mathematical analysis has suggested that, with correct sizing, the circuit is capable of maintaining the ΔV_{T} of correlating T₂ and T₀ with a shift of an approximate 3:2 ratio. The 3:2 ratio is the result of transistors T₂ and T₀ being voltage stressed in linear and saturation modes, respectively. The ratio is an indicator of the the amount of charge being stored in the channel of T₂ and T₀, respectively and appears in the charge-transfer compensation mechanism shown in Eqs. 3-4. Once the ratio is known, the geometries of T₂ and T₀ can be determined through Eqs. 1-15. The proposed 6T pixel circuit is configured to maintain this ratio throughout the circuit's operational lifetime, so that the self-compensating mechanism is achieved by raising Vᵢₙₜ with an amount generally equal to ΔV_{T,0} in the emitting phase. As a result, the output current is not affected by the bias-induced degradation of a-Si:H TFTs.

Eq. 15 also provides information on Lₒᵥₗ, which helps to downsize TFTs for better pixel density in, for example, a high-resolution display. If a lower overlap or a self-aligned process is used, the size of pixel TFTs, particularly T₂ and T₃, which are the largest TFTs in the pixel circuit, can be reduced. Indeed, a reduction in size can reduce the area needed by the pixel circuit, thereby achieving a better fill factor.

Under tensile strain, TFTs generally have slightly higher carrier mobility and much slower bias-induced degradation. On the other hand, when TFTs are bent under compressive strain, they have slightly lower mobility and relatively faster bias-induced degradation. Such behavior of the TFT under bending could be explained by the defect creation model where the external strain is relieving or deteriorating the weak Si—Si bonds. It has been found that when the bending direction is parallel to the current flow, i.e. the TFT L direction, the impact of bending is at the highest, especially to the long-term biased-induced instability. When the bending direction is perpendicular to the current flow, the impact of mechanical strain is relatively less. As such, in some embodiments the layout of the pixel circuit can be given special consideration such that the correlating T₂ and T₀ are in the same orientation and placed in proximity to each other. In this way, both TFTs will experience similar mechanical strain so that their relative degradation ratio of 3:2 will generally be maintained.

Simulation

A charged-based level-61 a-Si:H TFT model was used to simulate the behavior of the 6T pixel circuit under different bending situations with increasing electrical instability. The circuit and its test-bench have been implemented in Cadence Virtuoso environment with parameters listed in Table 1. The process parameters (μ_{eff}, C_{ch}, and Cₒᵥₗ) were obtained by extracting data from I-V and C-V curves of test TFTs with known geometries. The Lₒᵥₗ was set to 5 μm. The W/L of T₀ was set to 100 μm/20 μm as a reference to size all other TFTs. Switches T₄ and T₅ were chosen to be 25 μm/20 μm and 25 m/10 m, respectively, to minimize the pixel area guided by Eq. (15). Then, the size of T₂ was calculated to be ≈100 μm/100 μm. Lastly, T₃ was chosen to match the size of T₂ to restore charge needed by T₂ in the emitting phase. Note that the maximum V_{data} needs to be less than the difference between the on-state of V₂ and the V_{T} of T₅ (V₂^{high}−V_{T,5}). This condition was to guarantee that the V_{data} is always fully transferred onto Vᵢₙₜ in the emitting phase.

TABLE 1
Device and process parameters used in the simulation.

| Parameter | Value |
|---|---|
| W₀/L₀ (μm/μm) | 100/20 |
| W₁/L₁ (μm/μm) | 50/20 |
| W₂/L₂ (μm/μm) | 100/100 |
| W₃/L₃ (μm/μm) | 100/100 |
| W₄/L₄ (μm/μm) | 25/20 |
| W₅/L₅ (μm/μm) | 25/10 |
| Lₒᵥₗ (μm) | 5 |
| V_{data} (V) | 5~15 |
| V_{DD} (V) | 20 |
| V₁ (V) | 0~20 |
| V₂ (V) | 20~0 |
| μ_{eff} (cm²/Vs) | 1.0 |
| C_{ch} (fF/μm²) | 0.16 |
| Cₒᵥₗ (fF/μm²) | 0.22 |

First, to investigate the effectiveness of the self-compensating circuit on a flat substrate, ΔV_{T,0} was varied from 0 V to 3 V and ΔV_{T,2} from 0 V to 4.5 V to represent increasing electrical instability of the correlating TFTs. The simulation results indicated that the output current in the entire data range was able to retain more than 99% of its initial value when ΔV_{T,0}=3 V shown in FIG. 3. Then, to simulate the impact of mechanical strain onto the flexible substrate, a higher ΔV_{T,0} value of 4 V was chosen to represent a compressive stress and a lower ΔV_{T,0} value of 2 V was chosen to represent a tensile stress. The mobility of the TFTs was also slightly adjusted due to bending. When placed under tensile strain, 0.3% is added to the TFT mobility, and when under compressive strain, 0.3% is subtracted from the original value. In order to maintain the desired correlation between ΔV_{T,2} and ΔV_{T,0}, both T₂ and T₀ were assumed to have the same orientation and placed in close proximity in the layout. Therefore, their degradation could still have the 3:2 relationship. The pixel circuit was able to maintain ˜99% of its initial current under tensile and compressive stain tests shown in FIG. 3.

Additionally, simulations with T₂ and T₀ having perpendicular orientation were conducted: the strain was applied in parallel to the L direction of T0 and perpendicular to the L of T₂. When tensile strain was applied, the pixel circuit exhibited overcompensation, showing that the output current was ˜112% compared to the initial value shown as the dashed line with triangle symbols in FIG. 3. This is due to ΔV_{T,2}:ΔVT,0>3:2, so that T₂ was providing more charge which raised Vᵢₙₜ higher than expected. On the other hand, when compressive strain was applied, the pixel circuit demonstrated under-compensation. The output current only retained ˜92% of its initial value due to ΔV_{T,2}:Δ_{VT,0}<3:2 shown in as the dashed line with X symbols in FIG. 3. It appears that T₂ did not provide sufficient charge during the emitting phase, so that Vᵢₙₜ^{stressed} did not reach the correct value.

FIG. 3 shows the simulation of normalized output current of the 6T pixel circuit in the entire V_{data} range under various bending conditions. The solid lines with square, triangle, and X symbols show the compensation percentages under flat, tensile strain, and compressive strain conditions, respectively, when T₀ and T₂ are placed in parallel. The dashed lines with triangle and X symbols represent the compensation under tensile and compressive strains, respectively, when T₀ and T₂ are placed perpendicularly. The line with diamond symbols shows a pixel circuit without compensation when placed flat.

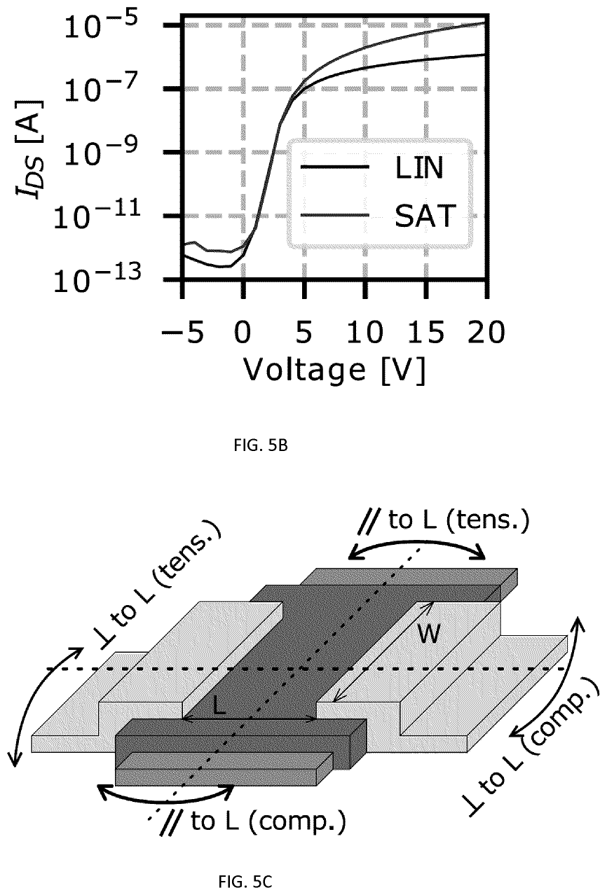

The 6T pixel circuits can be fabricated using a conventional 5-mask back-channel-etched (BCE) a-Si:H TFT process on flexible polyethylene naphthalate (PEN) substrates at a maximum process temperature of 170 C. The cross-section schematic of the fabricated a-Si:H TFT and measured I_{DS} vs. V_{GS} curves are shown in FIGS. 5A and 5B, respectively. The test TFT showed carrier mobility (μ_{eff}) of 1 cm²/V s, subthreshold slope (SS) ˜0.76V/dec, and V_{T}˜2.5 V.

Voltage-biased bending experiments of individual TFTs with four different modes were conducted to understand bending effects. The TFT was placed in tensile or compressive strain as well as in parallel or perpendicular to the L direction shown in FIG. 5C. The output current was logged periodically and the result was compared with a flat TFT as reference.

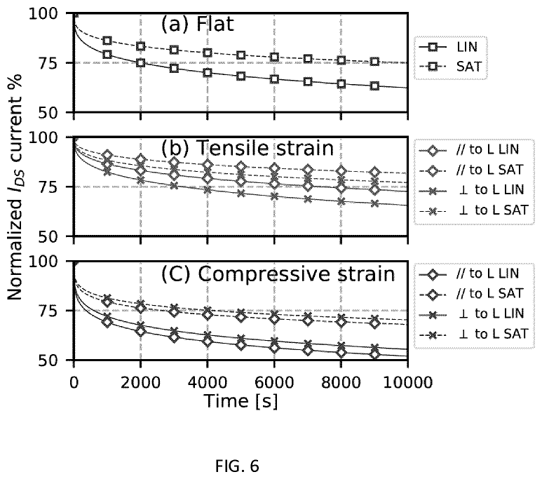

The normalized drain-source current (I_{DS}) of test TFTs with the same geometry (W/L=100 μm/20 μm) under four bending modes in saturation (V_{DS}=20 V and VGS=20 V) or linear (V_{DS}=1 V and V_{GS}=20 V) voltage-bias condition is shown in FIG. 6. The bending radius was ≈40 mm and the calculated strain was ε=±0.3%. TFTs under tensile strain showed lower bias-induced degradation compared to the reference flat TFT. On the other hand, compressive strain caused TFTs to degrade more under the same voltage bias. When the bending direction was in parallel with the L of TFTs, the impact of strain on degradation was generally more than the case of TFTs with strain perpendicular to L. Moreover, in all experiments, TFTs under linear mode were observed to degrade faster than in saturation mode under the same V_{GS}. The degradation ratio of linear to saturation modes was also confirmed to closely follow 3:2 which is the crucial design parameter for the 6T compensation pixel circuit.

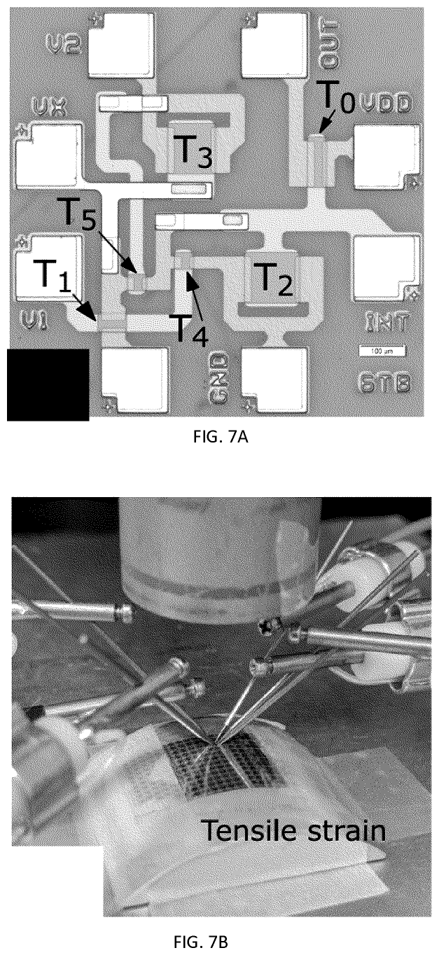

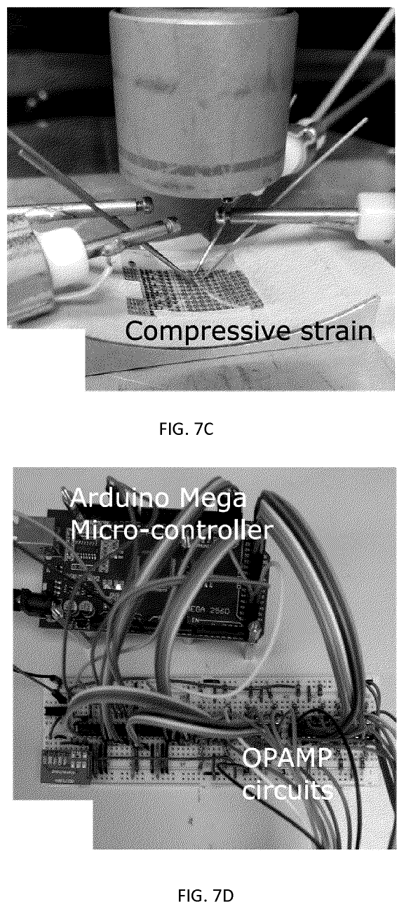

An optical micro-graph of the fabricated 6T pixel circuit is shown in FIG. 7A. The bending experiments were conducted by taping the substrate onto a convex (FIG. 7B) or a concave (FIG. 7C) metal sample holder with the same radius to obtain tensile or compressive strain, respectively. The power-supply voltage, data input, and control signals were generated according to Table 1 by a micro-controller with external digital-to-analog converters and operational amplifiers shown in FIG. 7D. The pixel circuit on the same PEN substrate was driven at the maximum V_{data}=15 V to mimic a worst-case TFT degradation while laid flat and bent with tensile or compressive strain of 0.3% for 24 hours under 60 Hz frequency. Note that the bending direction was parallel to the L of T₀ and T₂ so that the impact of mechanical strain was generally at a maximum. The output current of the pixel circuit was logged every 10 minutes through an analog-to-digital converter on-board the micro-controller.

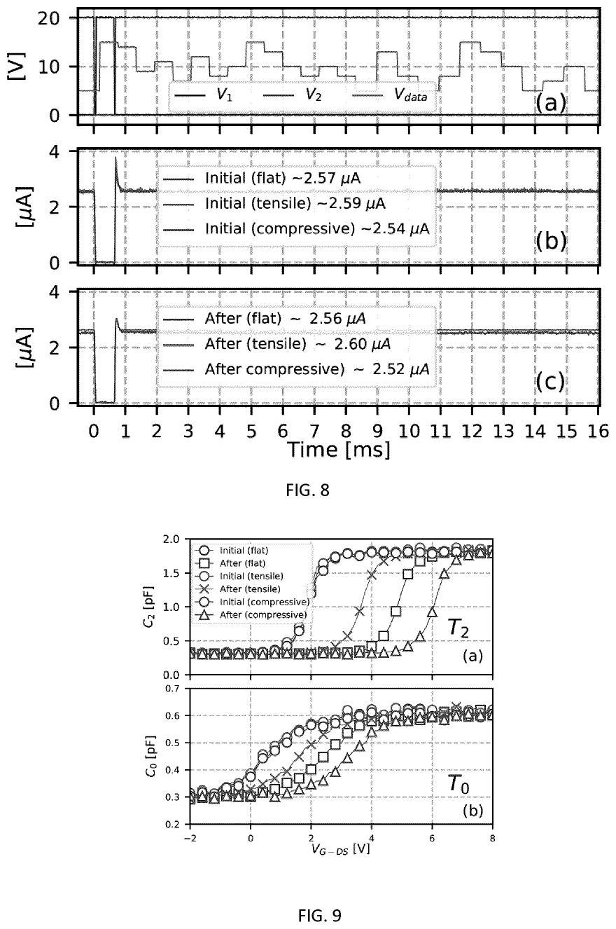

FIG. 8A shows the control signals of V₁, V₂, and V_{data}. The initial output current waveforms during a display cycle (60 Hz refresh rate) of the 6T pixel circuit are shown in FIG. 8B. All three cases with the pixel circuit being laid flat, and under tensile strain and compressive strain showed a slight variation in the initial output current values due to mobility change under bending. After 24-hour bias stress, the pixel circuits demonstrated a correct compensation behavior with less than ±1% variation (FIG. 8C) compared to the initial output current values with the same strain conditions in FIG. 8B. In contrast, the output current of a 2T uncompensated pixel circuit with the same initial current experienced more than 40% loss when placed flat (not shown here).

To investigate the effectiveness of the self-compensating charge-transfer mechanism of the 6T pixel circuit, C-V measurements were also performed on the correlating TFTs (T₂ and T₀). All the terminals of T₂ and T₀ were made available for probing in the pixel circuit shown in FIG. 7A. According to Eq. (5), the correlation ratio should be ΔV_{T,2}: ΔV_{T,0}=3:2. In the experimental results shown in FIGS. 9A and 9B, when the pixel circuit was laid flat during the test, ΔV_{T,2}=Δ3.15 V and ΔV_{T,0}=2.08 V, and the correlation value was 1.51. When under tensile strain, the measured C-V curves showed ΔV_{T,2}=1.78 V and ΔV_{T,0}=1.16 V, and the correlation value was 1.53. When under compressive strain, the C-V curves showed ΔV_{T,2}=4.17 V and ΔV_{T,0}=2.80 V, and the correlation value was 1.49. As a result, in all three long term bias stress experiments, the 6T pixel circuit demonstrated the correct correlation between T₂ and T₀, which provided the desired compensation behavior regardless of strain situations.

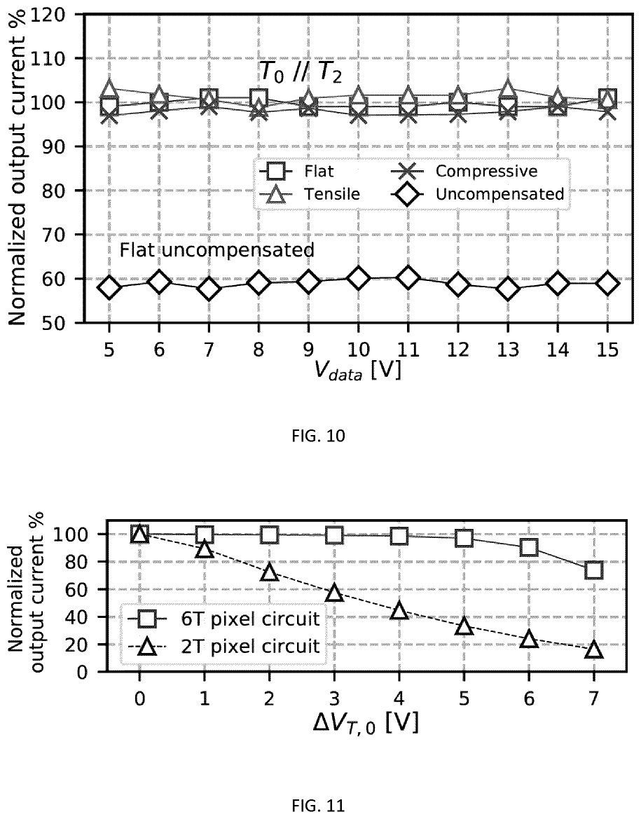

Three additional experiments with random V_{data} were also conducted with flat, tensile strain, and compressive strain conditions on the pixel circuit to verify the compensation capability in the entire data range after bias-stress for 24 hours. FIG. 10 shows the results of the 6T pixel circuit in comparison with the 2T uncompensated pixel circuit under flat condition. Note that the proposed pixel circuit exhibited less than ±3% of variation for all the situations while the output current of the uncompensated 2T pixel circuit was reduced by ˜40%.

The proposed 6T pixel circuit was compared with existing compensation methods in terms of number of TFTs, control signals, and performance. The 6T pixel circuit has the least amount of control signals and average TFT count. The 6T pixel circuit's footprint is also comparable to other charge-transfer pixel circuits and significantly less than circuits using other compensation methods. The compensation performance under flat and bending situations is superior to conventional solutions, demonstrating the efficacy of the proposed self-compensating pixel circuit for flexible displays. To further investigate any limitation of the 6T compensation pixel circuit, higher ΔV_{T,2} and ΔV_{T,0} values were applied to the simulation test-bench, while keeping the correlation ratio of 3:2. FIG. 11 shows the simulation of normalized output current of the 6T compensated and 2T uncompensated pixel circuits with a ΔV_{T,0} range from 0 V to 7 V under flat condition.

The simulation assumed a maximum V_{data}=15 V to mimic the anticipated worst-case degradation. It was observed that the compensation started to lose its effectiveness above ΔV_{T,0}=5 V. This phenomenon can generally be explained by the charge model of TFTs. Since the proposed compensation mechanism is to raise Vᵢₙₜ^{stressed} according to ΔV_{T,0}, Vᵢₙₜ^{stressed} from Eq. (6) becomes 20 V at ΔV_{T,0}=5 V. This made the difference between gate and drain terminals of T₀ almost zero. As a result, T₀ is no longer in saturation mode when ΔV_{T,0} is beyond 5 V. Therefore, the correlation of ΔV_{T,2}: ΔV_{T,0} becomes less than 3:2, decreasing the compensation capability.

In addition to the consideration of the ΔV_{T,0} limitation, the change of correlation ratio has an impact on the design of the 6T pixel circuit. When the correlation ratio is more than 3:2, the size of T2 and T3 can be reduced because more charge from T2 is supplied to facilitate the compensation. However, if the correlation ratio is less than 3:2, the size of T₂ and T₃ should be increased to reach the desired compensation based on Eq. (15). In this case, the allowed area of the pixel circuit on the display panel may dictate the size of T₂ and T₃. On the other hand, since interest in 4K or 8K display, augmented-reality (AR), and virtual-reality (VR) equipment have been growing, there is generally a need for faster operating speed and denser pixel displays. Despite the low carrier mobility of the a-Si:H TFTs, if they can be fabricated with design rules such as, for example, Lₒᵥₗ=1 μm and a minimum L of 5 μm, the footprint can be reduced to 1070 μm², which is less than 5% of the original size. The simulation assumed that the W/L of T₀ remains the same, while other TFTs were sized according to Eq. (15). Moreover, the significant reduction in Lₒᵥₗ can allow the pixel circuit to be operated at a higher frequency. In the proposed 6T pixel circuit, the speed is determined by the RC time constant when T₁ is charging the storage capacitor T₃. If a 1 μm overlap design rule is assumed, the simulated worst-case charging time is less than 3 μs satisfying, for example, a requirement for 200 Hz refresh rate in a 2K display panel. However, if used in a 400 Hz 4K display with more demanding requirements, a-Si:H technology may not be the ideal solution. In this case, high-mobility TFTs made by metal-oxide or LTPS technologies could be used to reduce the size of pixels and increase the operating speed.

Generally speaking, the self-compensating 6T pixel circuit with only two control signals can provide compensation capability on a flexible PEN substrate under mechanical strain through a reliable charge-transfer process and careful consideration of the layout. In particular, in experiments only ±3% variation from the initial output current was observed after long-term bias stress under various bending conditions. The mechanical manipulation also allows novel approaches to the design, sizing, operation, and control of the circuit, allowing a new degree of freedom that may be utilized through mechanical bending to regulate the circuit performance for flexible display applications.

The circuit embodiments herein are intended to be implemented in various technologies, such as, for example, digital displays, flat panel displays, sensor arrays and the like. It is also intended that the circuit embodiments can be implemented without using complex fabrication processes and can be implemented within a conventional thin-film micro-fabrication process.

It is intended that the circuit embodiments described herein be compatible with standard industrial technology. Further, it is intended that the circuit embodiments herein reduce costs since TFT technology is cheaper than CMOS technology and generally needs fewer contact pads and wire bondings. The embodiments herein may be integrated on the panel (glass or plastic) reducing the overall size of the product and the mechanical efficiency due to fewer off-panel connections. Lower cost may also be realized by the end user due to the lower power dissipation, due to the lower parasitics of the lines on the drivers.

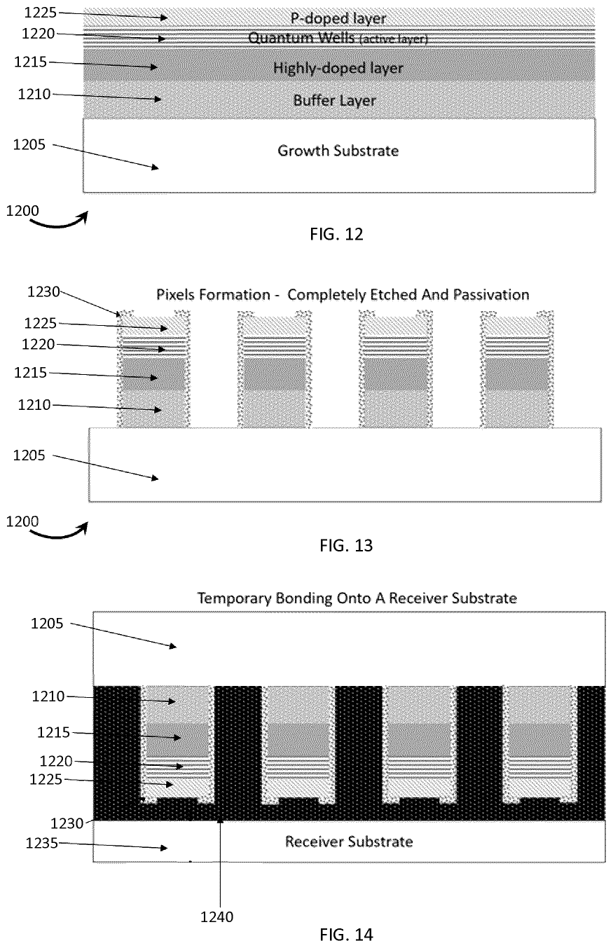

A method for fabrication of opto-electronic devices, such as LEDs or the like, is illustrated schematically in FIGS. 12-27. While the method is illustrated with regard to LEDs, one of skill in the art will understand that the same or similar techniques could be applied to other opto-electronic devices including sensors or the like. This process may be used, for example, for fabrication of the circuits noted above but may also be used for various other types of opto-electronic circuits as would also be understood by one of skill in the art.

In this process, FIG. 12 illustrates the heterostructure 1200 of a device, based on various layers being grown on a substrate, which may be a rigid substrate. The heterostructure 1200 of the device comprises a growth substrate 1205, a buffer layer 1210 coupled to the growth substrate 1205, a highly-doped layer 1215 coupled to the buffer layer 1210, a quantum well layer 1220 coupled to the highly-doped layer 1215, and a p-doped layer 1225 coupled to the quantum well layer 1220. In particular, FIG. 12 shows epitaxial structures of, for example, the light emitting devices described above, being grown on a growth substrate 1205. If the growth substrate 1205 and epitaxial film are not the same material, there could be a high defect density in the first several microns of the grown material attributed to crystal lattice mismatch and/or thermal expansion coefficient mismatch. These defects will generally degrade the light emission efficiency of the device if they exist in the quantum wells (active region). To solve this problem, the growth process starts with a buffer layer to compensate for defects. However, this buffer layer is typically undoped (high-resistance) and can be defective. Moreover, the thickness of the buffer layer is governed by the estimated defect density and the buffer layer may absorb or trap some part of the photons. As described further herein, removing the buffer layer and thinning the device is intended to improve the electrical properties of the light emitting devices. In some example embodiments, the growth substrate may be Si, Sapphire, GaAs, SiC, or the like. The epitaxial material may be Si, III-Vs such as GaN and GaAs, and II-VI or the like. In a specific example, commercially available GaN-based epitaxial thin-film structures can be used.

FIG. 13 show pixel (LED) formation by etching and passivation. In the example of light emitting devices, FIG. 13 illustrates forming discreet light emitting devices. For this purpose, it is necessary to pattern the epitaxial structures by using a wet or dry etching process. For example, a chlorine-based dry etching process can be used to remove the GaN from an unwanted area. A metallic or dielectric layer can be used as the etch-mask. However, after the etching process, defects can appear at the devices' sidewall originating from the dangling chemical bond. These defects can degrade the device's efficiency by increasing the non-radiative recombination rate of electron-hole pairs (the favorable process is a photon generation after radiative recombination of an electron-hole pair). As a result, the defects should be passivated chemically or physically by a dielectric passivation layer 1230. In addition, the dielectric passivation layer 1230 generally prevents any short circuit between p and n-side of the diode structure in the future metal deposition. The passivation layer can be formed from SiO₂, SiNₓ, Al₂O₃, or the like, and can be coated by plasma enhanced chemical vapor deposition (PECVD), atomic layer deposition (ALD) or other deposition techniques. In a particular example, 30 nm of Al₂O₃ was coated by using an ALD system.

FIG. 14 shows temporary bonding onto a receiver substrate using a temporary bonding and/or structural material 1240. In particular, the fabricated (pixelated) structures/devices are bonded onto a carrier substrate 1235, which can carry and release the devices onto a final substrate. The bonding material 1240 can be based on organic or inorganic chemistry and can be structural in the sense that the bonding material can help hold the pixel structures in place. In some cases, the bonding material 1240 may be coated on the carrier or device substrate or both of them by using, for example, a spin-coating technique to provide a uniform thickness. The bonding material 1240 chemistry can be different on a carrier or device substrate. In one example embodiment, the bonding material 1240 may be Xtalbond™, a commercial wax that is soluble in a solvent and melts at ˜60 C. By bringing the 2 substrates (device and carrier) together at a temperature more than the melting temperature of the bonding material, the two substrates can be bonded together. This operation can be done, for example, in a vacuum or vacuum annealing can be performed after, to remove any air bubbles or the like at the interface. In a particular case, the bonding process may be at 80° C. and vacuum processing can be performed after the bonding.

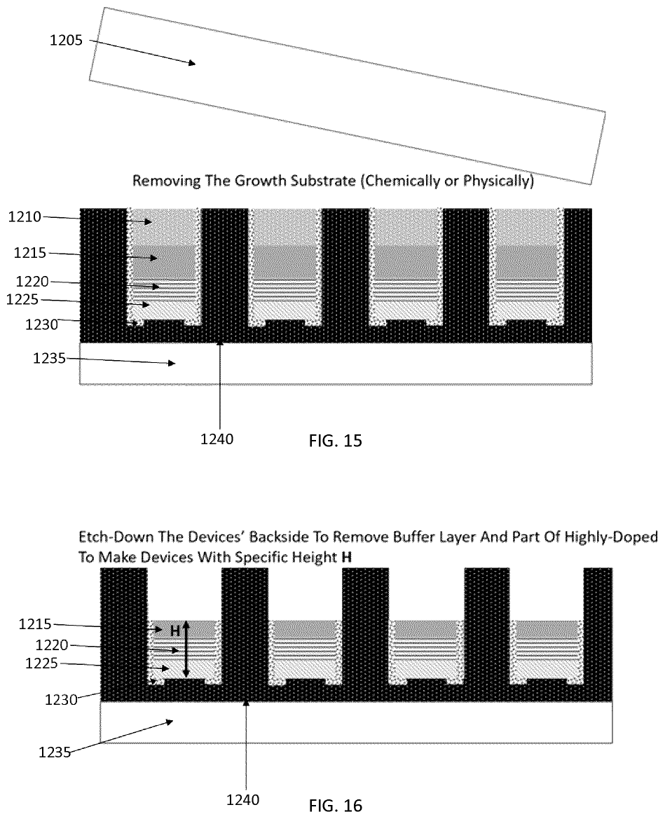

FIG. 15 shows the removal of the growth substrate 1205, which can be performed chemically or physically. Due to the nature of the process, the devices are typically attached robustly onto the growth substrate 1205. As a result, the removal of the growth substrate 1205 makes use of a physical process such as laser processing or a chemical process such as epitaxial lift-off or the like. In one embodiment, laser-lift-off was used to remove a sapphire substrate from GaN devices. In another embodiment, chemical etching was used to remove a GaAs substrate from GaAs-based devices. In the removal process, the bonding material 1240 keeps the devices in the same order (arrangement) and fixed in their original place during the transfer process. The result is that all the devices are transferred onto the carrier substrate 1235 in the same configuration.

FIG. 16 illustrates etching the backside of the pixels to remove the buffer layer 1210 and potentially also a part of the highly-doped layer 1215 to bring the devices to a predetermined height “H”. As noted above, the buffer layer 1210 is typically very resistive and can be defective. FIG. 16 illustrates removing the buffer layer 1210 by either chemical or physical etching. In an example, dry etching in chlorine-based gases was used to remove the buffer layer 1210 and provide access to the low-resistance n-doped layer 1215. In this situation, the total device structure behaves like an optical waveguide that can trap the generated photons. In order to provide the highest light extraction efficiency, the waveguide height may be optimized to maximize the out-coupling of light to the surrounding environment. As a result, engineering of the height of the device in this step is used to achieve height H, which provides the highest extraction efficiency. Depending on the type of device, the height H may range from a few tens of nanometers to several microns.

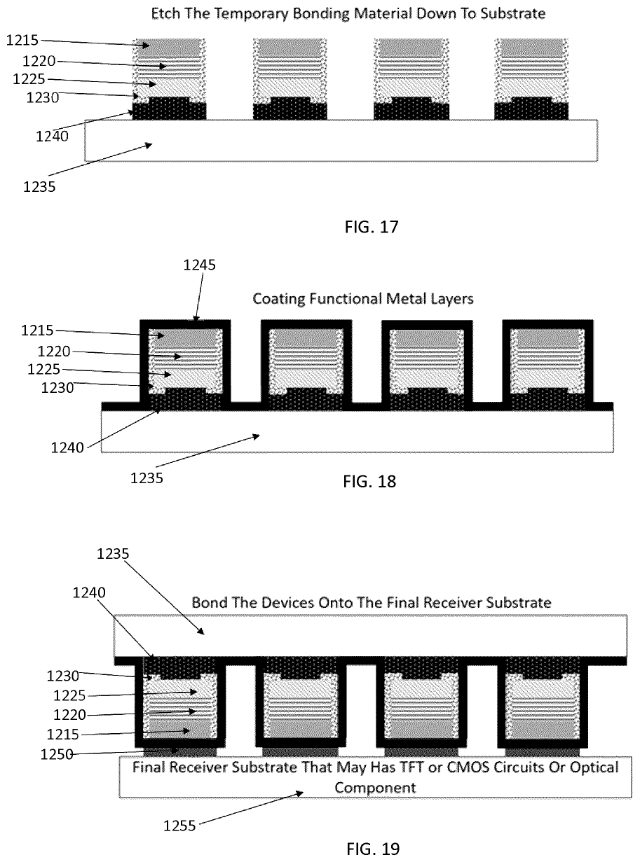

FIG. 17 shows the etching of the temporary bonding material 1240 away from the pixels. In particular, the device is prepared to be transferred onto the final receiver substrate by etching the temporary bonding material 1240 from the sidewall of the device. The temporary bonding etch process should be selective such that the passivation layer remains intact. In one example, an oxygen plasma was used to remove the bonding material from the sidewalls. This process was selective to remove the temporary bonding material 1240 from the sidewall of the device while leaving the Al₂O₃ passivation layer intact.

FIG. 18 illustrates the coating of functional metal layers 1245 on the pixels. In particular, functional metal layers 1245 may be provided onto the device backside or sidewall or both. By coating a reflective metal layer on the backside, the topside emission efficiency will be improved because the mirror-like metal layer reflects backside-emitted photons. Furthermore, by coating the sidewalls, the surrounding metal minimizes cross-talk between pixels by reflecting photons from the sidewall. For display applications, a black-resist is commonly used to stop cross-talk. However, black-resist generally absorbs part of the light and decreases the total light output performance. Due to the process outlined herein, it is easier and efficient to use a reflective metal and thereby improve light extraction efficiency.

The functional metal layer 1245 can also provide wettability for bonding the pixelated light emitting device onto the final receiver substrate. For the final bonding, in an example, an Indium-Gold class of material can be used. In some cases, the backside coating can be finished with gold when indium is already coated on the final substrate. When using indium, it is generally necessary to minimize the exposure of the indium metal to air since indium will oxidize over time and the bonding process may be adversely affected. In some cases, it can be beneficial to use aluminum to enhance the light reflection from the device backside and sidewall.

As a further development, the functional metal layer 1245 can be made from magnetic materials, such as, for example, nickel, iron and the like. In this case, the magnetic materials can act like a permanent spin valve, which changes the electrical properties of the device to allow only one electron spin to pass through the device. In this case, photons with only one polarization will be emitted from the light emitting device. This can be an effective application for backlighting applications in LCDs where a physical filter is used to stop one polarization of the light. The conventional approach of using a filter can waste 50% of the power by filtering 50% of the light whereas the use of magnetic materials could eliminate this loss.

Another example application of using the functional metal can be in forming a vertical cavity surface emitting laser (VCSEL). In this type of the laser, the light emission perpendicular from the top surface and the epitaxial structure starts with a distributed Bragg reflector (DBR). This reflector consists of several periodic layers with a thickness of a quarter of the emission wavelength to get the maximum reflection from the backside and then just pass light through the top-side. For example, some GaAs-based VCSELs have 30-period AlGaAs/GaAs to achieve a 99% reflector. Using the functional coating available through the process herein, it is possible to replace the backside distributed Bragg reflectors (DBRs) with a reflective metallic layer that has effectively 100% reflection. This approach can reduce both the cost and complexity of the process.

FIG. 19 shows the bonding of devices onto a final receiver substrate 1255. In some cases, the final receiver substrate 1255 may already include TFT or CMOS circuits or optical components. In particular, FIG. 19 shows a second transfer process, in which pixelated light emitting devices are transferred onto the final substrate 1255. The final substrate 1255 can, for example, be either rigid or flexible and can have CMOS or TFT driving circuits. In some embodiments, a bonding material 1250 such as gold, indium, palladium, or the like will be coated on the receiver substrate (the backplane side in display applications). Then the light emitting device (with functional metal layer) can be flip-chip bonded. The bonding itself can be based on eutectic, thermo compression, adhesive materials, or other related technology. In one example, the bonding temperature may be 150° C. for a flexible substrate and 250° C. for a silicon substrate.

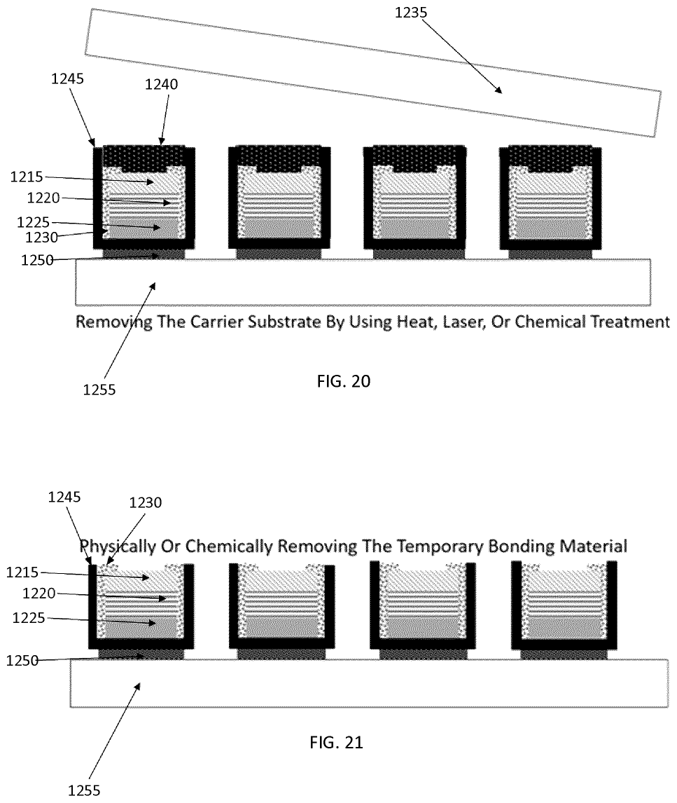

FIG. 20 shows the removal of the carrier/receiver substrate 1235, which may be performed by heat, laser or chemical treatment or the like. In particular, the carrier substrate 1235 will be removed (released) and the light emitting devices are supported on the final receiver substrate 1255. This release can be either by heating in order to melt the [NTD: temporary?]bonding material 1240 or by dipping the structure into a solvent that can dissolve the bonding material 1240. For example, the structure can be placed in warm acetone or IPA. The light emitting device(s) are fixed in place on the final receiver substrate because of the flip-chip bonding already completed.

FIG. 21 illustrates the removal of temporary bonding material 1240 from the pixels to leave the finished pixels. In some cases, any bonding material residues are removed by using an oxygen plasma or chemical solutions such as acetone or IPA.

In this process, various problems or issues have been overcome and the following description outlines some of the solutions implemented in embodiments of the method/process.

Growth Substrate

In circuit fabrication, type Ill-V materials (such as GaN) are commonly epitaxially grown on heterogenous substrates (such as SiC or Sapphire). The lattice constant and thermal expansion coefficient of the growth substrate generally do not match well with the epitaxial layers. To solve this problem, the growth process may start with a low-temperature nucleation buffer layer (commonly AlN or undoped-GaN) followed by growth of the main epitaxial layers at relatively higher temperatures. The buffer layer generally has a low carrier mobility and consequently a high series resistance. In addition, a typical high level of defect density at the buffer layer can decrease device reliability at high-voltage operation.

In embodiments of the process herein, by removing (etching) the buffer layer from the backside to reach devices' height H (when they are flipped onto a carrier substrate), as shown in FIG. 16, it is possible to remove/reduce the series resistance and improve reliability. This approach can be applied on devices in various categories of applications such as power electronics, optoelectronics and the like.

Transferring Devices to Final Receiver Substrate

When several transfer processes from different donor (carrier) substrates is required to make a system such as a micro-LED display, the transfer of additional devices may interfere with existing devices that are already on the final receiver substrate. This can be particularly difficult when adjacent devices are at the same height.

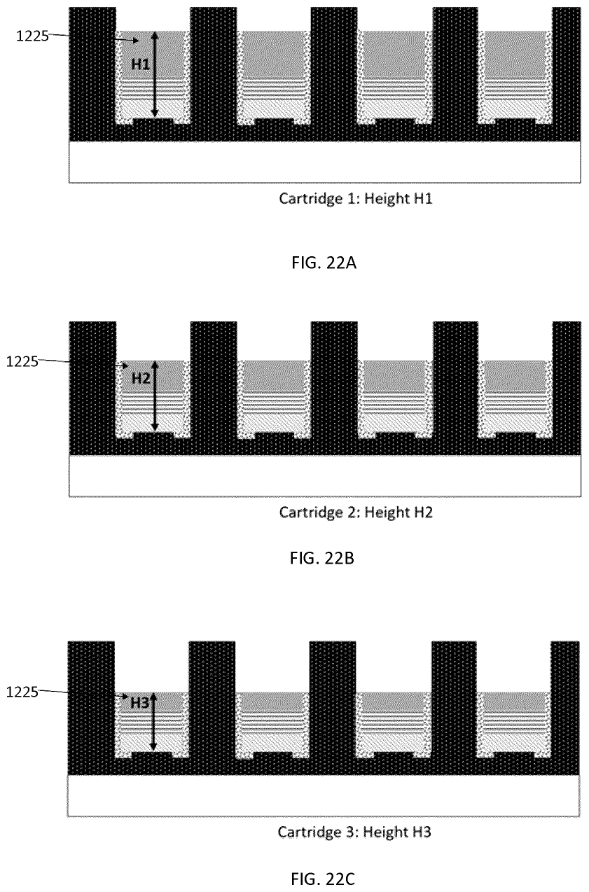

In embodiments of the method/process herein, as illustrated in FIGS. 22A to 22C, after transferring devices from the growth substrate onto a carrier substrate, each group of devices can be etched back (thinned) until a specific height (for example H1, H2, H3) (i.e. similar to FIG. 16 in the process described above). As a result, each device (pixel) will have a desired device thickness. This is useful because when performing a several step transfer of light-emitting devices onto a carrier substrate, it can be very important to include various devices while also preventing interference between adjacent devices. It can, however, be difficult to prepare devices having different heights on a single substrate because there is not always enough freedom in the epitaxial growth process to make the devices very tall or short. By using the back-side etching technique described above, it is possible to adjust the height for each group of devices. In particular, this height engineering process can be done when devices are transferred onto the carrier substrate. As shown in FIGS. 22A-C, one group of devices (such as blue LEDs) can be etched back to the height H1, another group to height H2 and another group to H3. This approach enables the sequential-transfer of devices having different heights without the interference of each group of devices with the already transferred devices on the receiver substrate. In particular, the final transfer from the intermediate substrate onto the receiver substrate can then start from the thinnest device and be followed by thicker ones. In this way, because of difference in devices' height, micro devices can be transferred from different donor substrates onto a final receiver substrate without interference.

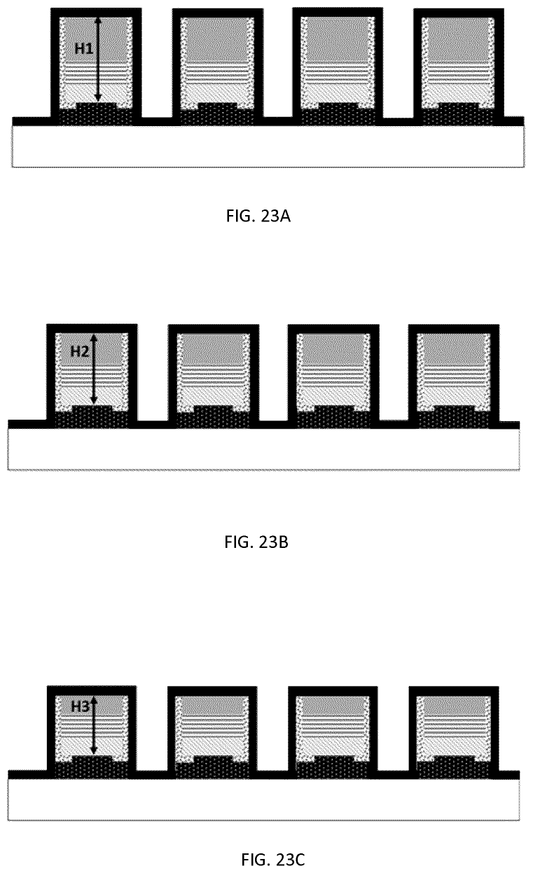

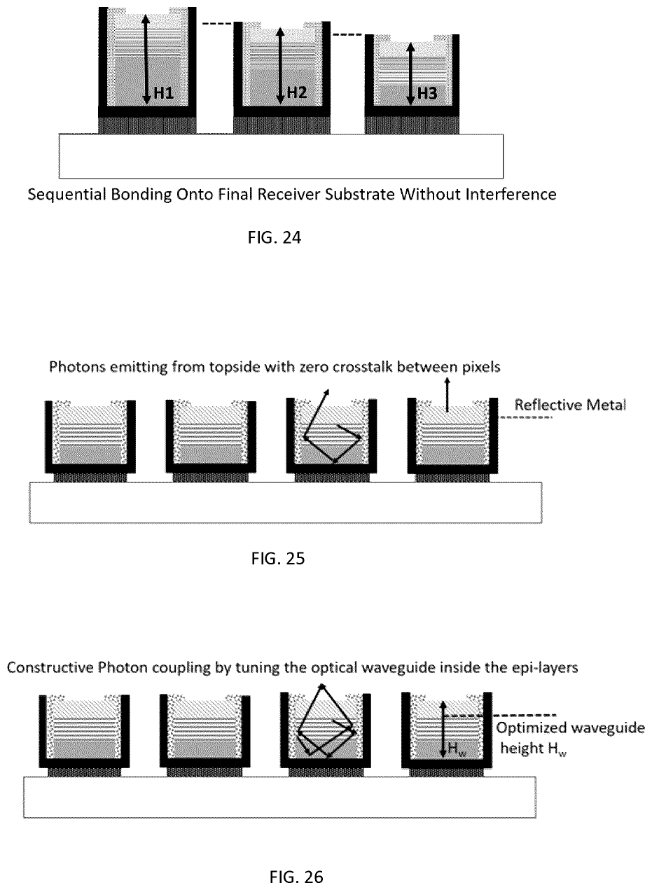

The process of transferring is illustrated in FIGS. 23A-C and FIG. 24, in which FIGS. 23A-C show the different height devices on their carrier substrate and FIG. 24 shows 3 devices after transfer to a final receiver substrate. In the transfer, since various different height devices are being transferred (sometimes referred to as a multi-transfer), a metal on the receiver substrate should be resistant against oxidation and have electrical properties that will not be degraded during the multi-transfer process. As a result, an inert metal such as gold can be used on the receiver substrate. A bonding agent metal such as indium or tin can be coated on the device's backside. In this case, indium is a low-melting point metal bonding layer that is in contact with the receiver substrate for effective bonding. The bonding metal may be on top of this metal contact and is usually only used as an adhesive layer that is also in electrical contact to the electrode. In the case above, gold is placed on the receiver substrate since the metal contact may be exposed to ambient environment for a period of time before bonding is made and is preferably inert. In a particular case, a triple layer of silver/copper/tin can be used on the devices' backside. In this case, silver (Ag) provides a low-resistance ohmic contact onto the device, copper and tin provide the bonding function. In some cases, the coating for the electrical contact may be 10-100 nm thick and the bonding layers may be between 500 nm to a few microns thick. This may be in addition to the functional layer. For example, in some cases, the Ag may be 20-50 nm thick since it is used as an electrical contact. The functional coating is then the Cu or Sn layer and that may be much thicker, up to a few microns. The higher thickness can be used to compensate for physical aperities and roughness of the surface that is being bonded. One of skill in the art will understand that different thicknesses and materials may be used depending on the application/requirements. FIG. 24 shows the final receiver substrate after completion of the transfers. In each transfer (for example, flip-chip bonding or the like) from any of the carrier substrates, only one or a series of devices with the same height may be transferred. In this case, the order of the transfer starts from H₃, then H₂, and finally H₁ (the heights (H) are such that H₃<H₂<H₁). As H₃ is smaller in height, during the transfer of the H₂ and then similarly H₁ there should be no interference between pixels. It will be understood that the devices at each height can be placed on the transfer substrate at appropriate spacing to allow placement on the final receiver substrate in co-ordination with the other devices.

Emission Efficiency

Optoelectrical devices (micro-LEDs for example) normally include a reflective coating on a backside to reflect photons emitted downward back toward the emission surface. By bonding a metallized surface onto a receiver substrate, a higher light extraction efficiency is feasible. However, in a conventional situation, due to emission from the sidewall, optical crosstalk between adjacent pixels can still be a problem. In addition, packaging loss can be a significant problem in ultraviolet LEDs. The poor reflection of inner walls of some device packages can be due to a conventional sintering technique used for making the packages. Furthermore, in some cases a part of the light may be absorbed by the medium or an adjacent device, which may cause overheating.

In embodiments of the method/process herein, it is convenient and efficient to cover a device's backside and sidewalls with a reflective metal layer in order to reduce crosstalk between adjacent pixels (devices) and improve directional light extraction efficiency (see, for example, FIG. 18 in which a device can be easily coated with a functional metal layer). Thus, generated light will be reflected towards the device's topside once placed on the final receiver substrate, as illustrated in FIG. 25. FIG. 25 illustrates how the functional metal coating on the sidewall reduces/prevents cross-talk between adjacent pixels. In addition, the functional metal coating provides a top-side directional emission from each pixel. This top-side emission will be very applicable for display applications in various ways. For example, it improves the display brightness by guiding photons through the device topside. Further, if a color conversion technique (such as using quantum dots (QDs)) is used to produce red and green light from blue LEDs, this side-wall reflective structure reduces/prevents erroneous emission by QDs mounted on neighbor LEDs. As a result, the coating enables a more pure emission from QD layers.

Generation Efficiency

To make a more efficient GaN light-emitting diode, a thick epitaxial layer is generally required to compensate for defects that can originate during growth. However, if there is a thicker epitaxial layer, some of the photons emitted from the active layer (e.g. Quantum Wells) may be absorbed in this epitaxial layer and, thus, result in reduced efficiency. Moreover, multiple optical modes may be confined in the thicker epitaxial layer and degrade LED efficiency by destructive photon coupling inside the layer. In order to improve the light extraction efficiency, an optimized optical waveguide thickness for the epitaxial layer is generally required to reduce the total internal reflection and allow for coupling of photons in air constructively. However, even in this case, changes in the epitaxial layer during growth may degrade electrical performance of the devices.

In embodiments of the method/process herein, it is possible to tune the thickness and consistency of the epitaxial layer by etching the device from the backside after the first transfer (see for example, FIG. 16). This process allows for an optimized thickness of the epitaxial layer and, thus, a boosting of the LED's light extraction/generation efficiency, as illustrated in FIG. 26. In particular, considering the electromagnetic wave nature of the photons, the waves may be described as a sinusoidal function with unique amplitude and phase. Two electromagnetic waves interact constructively if they have the same phase. Conversely, they will nullify each other if they have a 180 degree phase shift. As a result, it is very important to get the maximum constructive interaction between the photons leaving the light-emitting topside. As the photons' pathway length defines the shift in their phase, obtaining maximum light extraction efficiency requires an optimum design of the light-emitting waveguide. In embodiments of the method herein, higher light extraction efficiency can be obtained by removing any undesired thickness of the LEDs when they are transferred onto the carrier substrate. A theoretical calculation shows maximum light extraction can be achieved when the height of each device is around 1 μm. However, the conventional height of the epitaxial structure is currently around 6 μm and obtaining a smaller height is almost impossible with conventional fabrication. Further, in conventional processing, making epitaxial structures thinner can reduce light extraction efficiency by increasing defect densities within the diode device. In embodiments of the fabrication method herein, it is possible to use thicker epitaxial structures from commercial vendors and then tune the device height as described herein. Generally speaking, the process is flexible and can provide any of various device heights by controlling the etch process time.

Sidewall Passivation

In order to make high resolution displays and image sensors, the size of each pixel (device) needs to be reduced, now in the range of several microns. However, when reducing the size, the surface to volume ratio increases, which can result in higher defect densities at the device's sidewall. These defects can act as unwanted recombination centers at which electron-hole pairs can recombine and consequently degrade the device's overall efficiency. Sidewall passivation is a conventional approach to mitigate this efficiency reduction. However, simply by having a similar concentration of electrons and holes near the defect centers, there remains a high chance of non-radiative recombination.

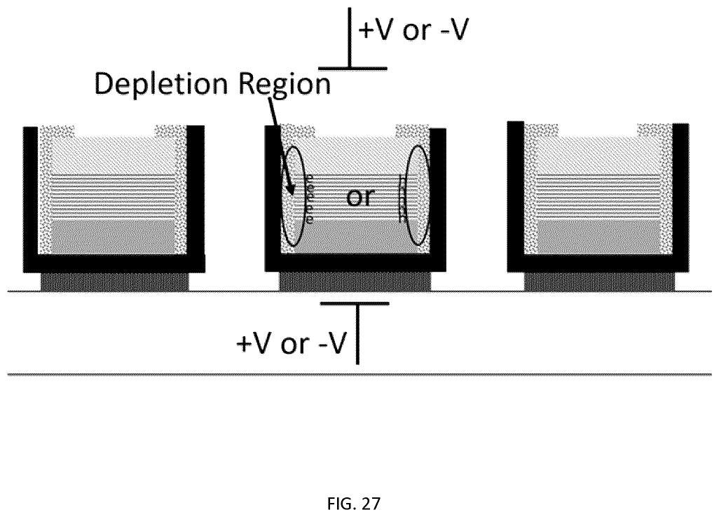

In embodiments of the method/process herein, the process and structure help to reduce non-radiative recombination at the defect centers at the sidewalls by reducing the recombination probability around those centers. For example, during a dry etching process, a number of defects will generally be made at the device sidewall due to surface dangling bonds. Those defects can act as traps for electrons and holes. When an electron and a hole reach the same defect site, they will tend to recombine with each other without producing light. As a result, the final LED light output efficiency will be degraded. One way to mitigate this non-radiative recombination is passivating the dangling bonds with a physically or chemically deposited layer (as described above). However, this technique is generally not 100% efficient. If the sidewall of the device can be depleted of one type of carrier (either electron or hole), then recombination at the defect sites can be reduced, possibly to zero. In embodiments of the method herein, the functional metal coated on the sidewall can be connected to one of the electrodes such that, during electrical bias of the metal, a field is generated that depletes one type of the carrier into the inner part of the device by a gating effect through the passivation dielectric. Generally speaking, the formation of a functional metal layer on the sidewall of a device acts like a gate electrode and depletes one kind of carriers (electrons or holes) from the sidewall as illustrated in FIG. 27. As a result, the probability of recombination will drop because of depleting the region of one kind of carriers. In this embodiment, the functional metal layer is the same metal layer that is used to improve the device's light extraction efficiency and bonding. As such, this self-gating effect does not require additional metal coating or additional pads on the read-out circuit. As a result, this functional metal layer represents a self-aligned contact with low fabrication complexity and cost.

LED Matte

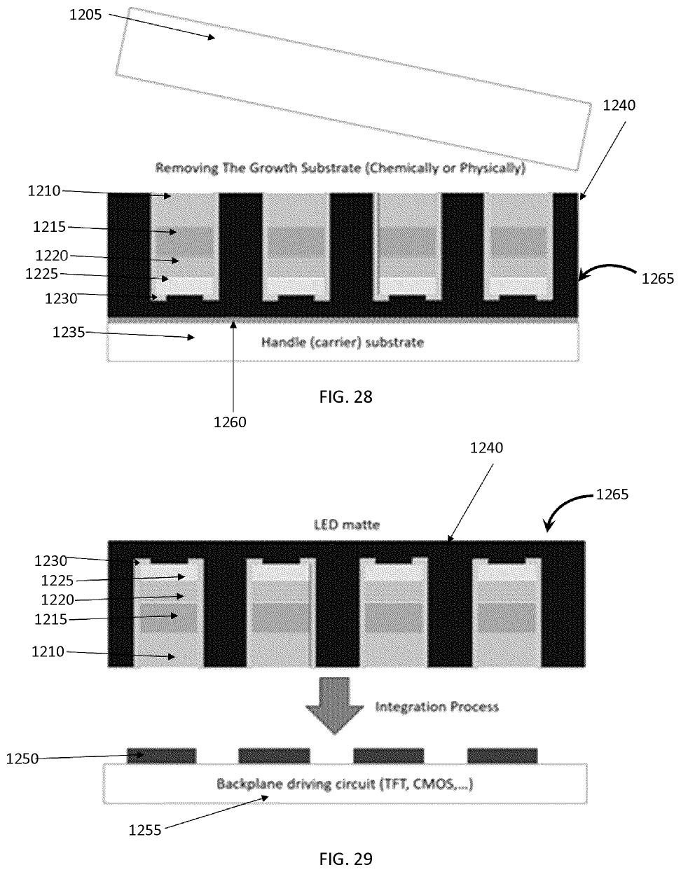

In some embodiments of the method/process herein, it is possible to fabricate a LED matte 1265 as illustrated in FIGS. 28-34. The LED matte 1265 is an array of LEDs that are held together using a bonding material 1240 as illustrated in FIG. 28. The LED matte includes a plurality of LEDs that may have been produced using a conventional process or the fabrication method described herein. In this particular example, the LED matte 1265 includes LEDs and a bonding material in a configuration such as that shown in FIG. 15. The bonding material can be clear or opaque, which may help to isolate the LEDs. Examples of potential bonding materials include polyimide, benzocyclobutene (BCB), SU8 and the like. The LEDs will generally include elements such as the buffer layer 1210, the highly-doped layer 1215, the quantum well layer 1220, the p-doped layer 1225, and the dielectric passivation layer 1230. In other embodiments, the LEDs may be processed through to the stage shown in FIG. 18 such that the LEDs may include the functional metal layer described above, after which bonding material may be applied to produce an LED matte.

In some cases, the LED matte 1265 may be prepared by transferring the fabricated structures/devices from a growth substrate onto a carrier substrate 1235 via a release layer 1260. The release material may be used for temporarily bonding the LED matte 1265 on to the carrier substrate 1235. FIG. 28 depicts the bonding of the LED matte 1265 to a release layer 1260 and removal, for example, by delamination, of the LED matte 1265 from the growth substrate 1235. The release layer 1260 may be a polymer material that is soluble in organic solvent (for example acetone or isopropyl alcohol) or a thermally releasable polymer or the like. In some cases, the LED matte 1265 may also be removed from the handle (carrier) substrate, for example by washing or etching in a chemical solution. The LED matte 1265 may alternatively be delaminated from the carrier substrate 1235 by laser irradiation through the carrier substrate. The LED matte 1265 may alternatively be delaminated from the carrier substrate 1235 by applying temperature when the release layer 1260 is a thermally releasable polymer.

The release layer 1260 may be applied to the carrier substrate 1235 by using a spin coating technique or mounting a tape on the carrier. The LED matte 1265 is then adhered to the carrier substrate 1235 via the release layer 1260. The release layer 1260 may have adhesive properties that keep the matte fixed on the carrier substrate 1235 during removal of the growth substrate or other operations. In some cases, the thickness of the release layer may be on the order of several microns, for example from 5 to 500 μm. If a soluble polymer is used for the release layer 1260, a spin coating method can be used to coat a layer of release layer 1260 onto the carrier substrate 1260, with the thickness of the release layer 1260 defined by setting the spin speed and time.

The LED matte 1265 may be delaminated from the carrier substrate 1235 to produce a freestanding LED matte 1265 or may only be released once bonded to another element as noted herein. Once the carrier substrate 1235 is removed, the LED matte 1265 may be transferred and laminated onto various platforms (e.g. a flexible display backplane) in, for example, a similar wafer bonding approach as described herein. In the example here, the LED matte is transferred onto a backplane substrate 1255 as illustrated in FIG. 29. In some cases, even if the LED matte is not exactly planar, the LED matte may be flexible enough to overcome any issues and still allow contact. This will depend on spacing, bonding material and the like but can be configured depending on the processing options.

The pads 1250 on the backplane driving circuit 1255 act as the electrical connection between LEDs in the LED matte 1265 and the backplane driving circuit 1255. The pads 1250 are configured to bond to the LEDs in the LED matte 1265 and to keep the LEDs aligned. The pads 1250 can be made from different metals such as indium or tin or a bilayer or multi-layer of metals such as Ti/In, In/Ag, In/Au, or Ti/Ni/Au. In addition, the melting point of the bonding pads may be low enough to prevent any thermal degradation to the LED matte 1265. For example, the melting point of In/Ag is 144° C. After putting the LED matte 1265 on the pads 1250, increasing the temperature to the melting point of the pads 1250 bonds the LEDs onto the pads 1250, and after decreasing the temperature to room temperature, the LEDs are attached to the metallic pads 1250. A layer of metal can alternatively be coated on a backside of LEDs when they are embedded in the LED matte 1265.

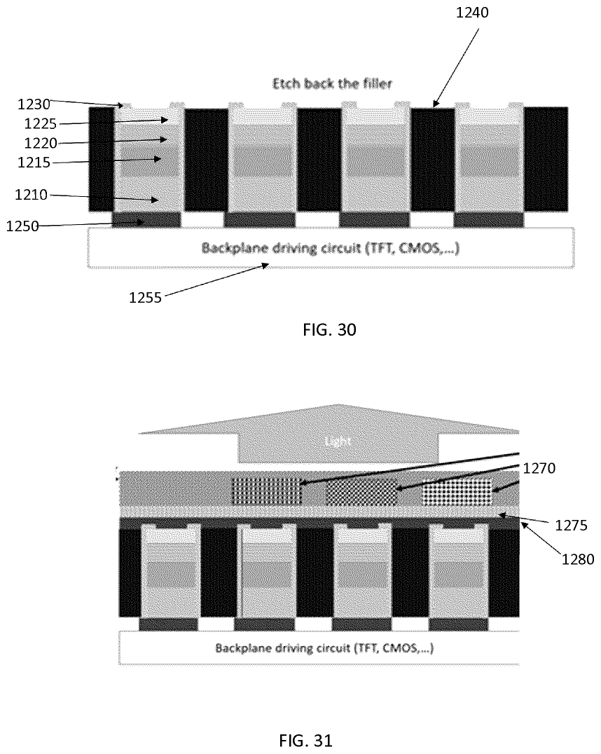

In addition, the gap between the pads 1250 can be filled with another polymer that can be bonded to the filler between LEDs to make a class of metal-metal polymer-polymer bonding to improve the bonding yield of the process. After bonding the LED matte 1265 to the backplane structure 1255 via the pads 1250, the LED matte 1265 may be processed using standard microfabrication techniques to finalize the pixel structure and form a pixel array as illustrated in FIG. 30 (e.g. the filler may be etched back or the like).

In some cases, as depicted in FIG. 31, the LED array (LED matte) may be connected with a light conversion layer for extended color capability. The light conversion layer may include various light conversion elements and also an encapsulation layer. In this particular example, the LEDs comprising the LED matte 1265 are monochrome but it can be advantageous to have a plurality of colors (e.g. Red-Green-Blue (RGB)) to make a display. Two, three, or more colors may be made from monochrome LEDs by employing down conversion of the emitted photons from the LEDs. For example, the LEDs may emit 450 nm (blue); these photons can be absorbed by light conversion elements 1270 (such as quantum dots, QDs). The absorbed photons may then be emitted by the light conversion elements 1270 in lower energies, for example green (510 nm) or red (610 nm) photons. Alternatively, the light emitted by the LEDs may be ultraviolet and all three RGB can be made by light conversion elements 1270. The light conversion elements 1270 on each LED may be different from the light conversion elements 1270 of each neighboring LED and may emit a different wavelength. The light conversion elements 1270 may need to be integrated with the LED matte 1265 in several steps (for example several lithography or printing steps). Finally, an encapsulation layer to protect the LED matte and light conversion layer from the ambient environmental conditions (humidity, dust, etc.) may be added. As shown in FIG. 31, the light conversion layer may be formed on top of a passivation layer and a top contact for the LEDs. The finished structure may include other layers as would be understood.

An advantage for this approach to creating an LED matte 1265 is the possibility to “peel” off a large area of LEDs bonded together such that the LEDs will generally stay aligned with each other within the bonding material 1240 that forms the LED matte 1265. The LED matte 1265 may be fully flexible and scalable to larger areas. The size of the LED matte 1265 may be changed, as well as the pitch of the array, before fabricating the LED matte 1265, in order to change the resolution of the LED matte to match the resolution of the backplane. The LED matte 1265 may replace any need for a “pick and place” technique to allow the placement of large numbers of LEDs over varying areas with a single lamination step. The LED matte 1265 may be a stand-alone product to provide sheets of LEDs that customers may use as a display media, for example to be laminated to their own backplane systems.

In some embodiments, rather than creating the LED matte and adding the light conversion layer, the LED matte may be fabricated to include the light conversion layer (including light conversion elements), sometimes called a “display media”. In this way, the LED matte 1265 will already contain pixels having all three primary colors such that, after a lamination stage, a full color display may be realized.

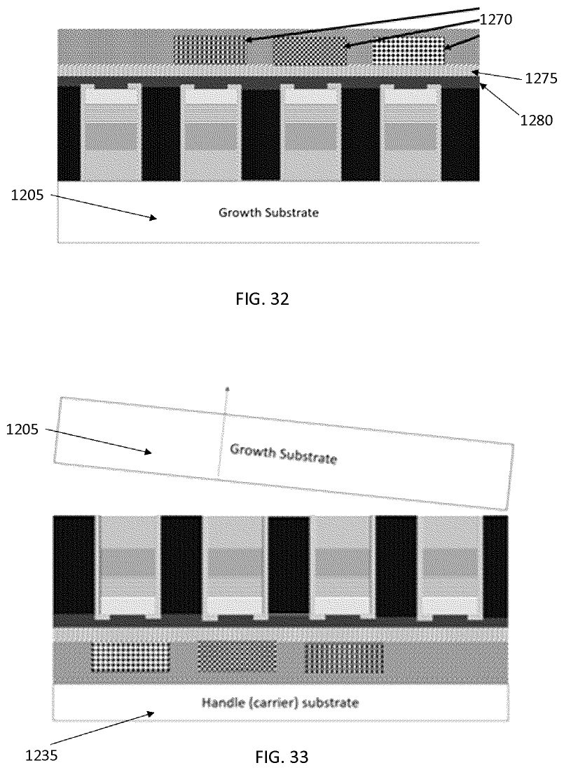

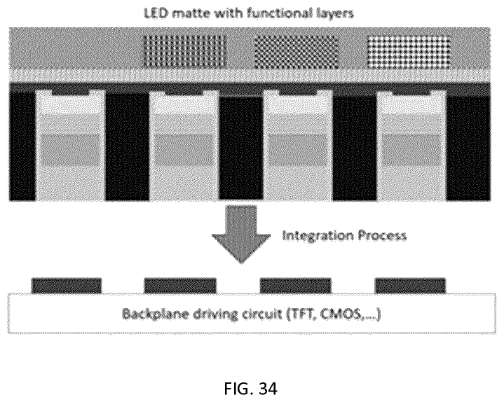

FIG. 32 depicts an exemplary LED matte 1265 still attached to the growth substrate 1205 (e.g. sapphire). In this embodiment, the LED matte 1265 further comprises a passivation layer 1275, a top contact 1280, and the light conversion layer (light conversion elements 1270 and encapsulation layer). The top contact 1280 may be a transparent conductive oxide, silver nanowires, transparent conductor, or the like. In this embodiment, the whole display emitters (RGB) are made on the growth substrate 1205 and may be detached from the growth substrate 1205 after flip bonding of them onto a carrier substrate 1235, for example using a release layer 1260 or the like as depicted in FIG. 33. Finally, the complete LED matte 1265 including the light conversion materials 1270 may be integrated onto a backplane structure 1255 as depicted in FIG. 34 to provide a final structure such as that in FIG. 31. The carrier substrate 1235 may be released by deactivating/releasing the release layer 1260 either before or after the application to the backplane. When the LED matte 1265 is detached from the carrier substrate 1235 prior to other connection/bonding, it is sometimes referred to as a freestanding LED matte 1265.

As noted above, in some embodiments, the backside etching of the buffer layer (as described with regard to FIG. 16) and/or the functional metal (as described with regard to FIG. 18) may be applied in the fabrications of the LED matte. As described herein, these additional stages are intended to make the LEDs more efficient. Furthermore, in some embodiments, the process of making a height difference among LEDs to, for example, provide additional height for bonding can also be used. In other words, the LED matte concept is typically compatible with the other LED processing methods as described herein and may be combined therewith.

Cost reduction is an intended benefit of embodiments of the method/process herein and is expected to provide a major benefit over low temperature poly-silicon (LTPS) TFT technology. The fabrication process uses individual process steps that are generally known and available for a-Si:H TFTs on glass or flexible substrates. In addition, the devices/LEDs produced are expected to be more efficient and less power-hungry.

Embodiments herein are expected to provide lower cost flexible display products made using a-Si:H technology. The adoption of this technology does not require high cost capital equipment expenditures because it uses generally available processes that are currently used in, for example, TV panel fabrication facilities. In addition, the thinning and bonding processes enable efficient use of conventional RGB micro-LED display technology.

In one aspect herein, there is provided a circuit design for an opto-electronic device, such as a pixel, that uses a charge-transfer method to maintain output current level regardless of TFT degradation (age or bending). Further, embodiments herein allow for an extension to implement the pixel circuit in an array to form a display panel backplane. In another aspect herein, a method of fabrication, including a thinning and bonding process, is applied to optical devices to enable efficient multi-color transfer onto various substrates.

It is anticipated that embodiments herein can be applied to flexible display applications, large area active-matrix display applications, imaging sensors, reflectors, filters and the like.

Embodiments herein are intend to have one or more of the following objectives: maintain a stable output current from the pixel circuit under voltage stress as well as mechanical bending; provide a pixel circuit with fewer inputs for ease of operation and convenience for scaling to address higher resolution displays; reduce the light-on voltage and current of optical devices to enable lower power operation; enhance the light extraction of optical devices; enable the multi-transfer process from different substrates onto a final receiver substrate; and reducing cross-talk between adjacent optical devices to enhance the contrast ratio.

In the preceding description, for purposes of explanation, numerous details are set forth in order to provide a thorough understanding of the embodiments. However, it will be apparent to one skilled in the art that some specific details may not be required. In other instances, well-known structures may be shown in block diagram form in order not to obscure the understanding. For example, specific details are not provided as to whether some aspects of the embodiments described herein are implemented as a software routine, hardware circuit, firmware, or a combination thereof. It will also be understood that elements of one embodiment may be substituted into other embodiments and that some embodiments may include elements that may not be required but are included for completeness or as an optional element.

The above-described embodiments are intended to be examples only. Alterations, modifications and variations can be effected to the particular embodiments by those of skill in the art without departing from the scope, which is defined solely by the claims appended hereto.

1. An electronic circuit for thin-film transistor degradation compensation, the circuit comprising:
a driving TFT that supplies current from a driving source to a load;
a compensation TFT, configured as a capacitor, that is provided between gate and source terminals of the driving TFT;
a storage TFT, configured as a capacitor;
a plurality of switching TFTs, configured to act as switches;
two control signals, comprising a row-select signal and a boosting signal;
an input signal;
wherein, when the row-select signal is on and the boosting signal is off, the plurality of switches are set such that charge flows from the input signal to the storage TFT and when the row-select signal is off and the boosting signal is on, the plurality of switches are set such that charge flows from the storage TFT to the compensation TFT and a gate of the driving TFT, such that the compensation TFT compensates for degradation of the driving TFT.

2. An electronic circuit according to claim 1, wherein the geometry of the driving and compensation TFTs is configured to balance charge components in the emitting phase.

3. An electronic circuit according to claim 1, wherein the geometry of the driving and compensation TFTs is configured based on bending forces on the driving and compensation TFTs.

4. An electronic circuit according to claim 1, wherein the plurality of switching TFTs is configured to isolate the compensation TFT and the gate of the driving TFT from interference of the input signal.

5. An electronic circuit according to claim 1, wherein the plurality of switching TFTs is configured to allow acquisition of the input signal without cross-talk to neighboring pixels.

6. An electronic circuit according to claim 1, wherein the plurality of switching TFTs comprises 3 TFTs.

7. An opto-electronic fabrication method comprising:
forming at least one opto-electronic device on a growth substrate, wherein the opto-electronic device comprises a buffer layer and an epitaxial layer;
temporarily bonding the at least one opto-electronic device to a carrier substrate via a bonding material;
removal of the growth substrate;
etching at least the buffer layer to bring the at least one opto-electronic device to a predetermined height from the carrier substrate;
etching the carrier bonding material away from edges of the at least one opto-electronic device;
coating the at least one opto-electronic device with a functional metal layer;
bonding the at least one opto-electronic device onto a final receiver substrate; and
removing the carrier substrate.

8. An opto-electronic fabrication method according to claim 7, wherein the epitaxial layer comprises a p-doped layer, an active layer comprising quantum wells, and a highly doped layer.

9. An opto-electronic fabrication method according to claim 7, wherein the etching at least a buffer layer further comprises etching a predetermined portion of the highly doped layer.

10. An opto-electronic fabrication method according to claim 7, wherein the etching at least the buffer layer to a predetermined height is selected to maximize the out-coupling of light from the opto-electronic device.

11. An opto-electronic fabrication method according to claim 7, wherein the final receiver substrate comprises at least one driving circuit for the at least one opto-electronic device.

12. An opto-electronic fabrication method according to claim 7, further comprising repeating the method to the coating the at least one opto-electronic device with a functional metal layer for a plurality of opto-electronic devices, each having a different predetermined height and then repeating the bonding the at least one opto-electronic device onto a final receiver substrate for each of the plurality of opto-electronic devices from shorter predetermined height to taller predetermined height.

13. An opto-electronic fabrication method according to claim 7, wherein the bonding the at least one opto-electronic device onto the final receiver substrate comprises bonding using an inert metal on the receiver substrate and a bonding agent metal on the at least one opto-electronic device and bringing the inert metal into contact with the bonding agent metal.

14. An opto-electronic fabrication method comprising:
forming at least one opto-electronic device on a growth substrate;
adding a bonding/structural material around the at least one opto-electronic device to form an opto-electronic matte;
temporarily bonding the at least one opto-electronic device to a carrier substrate;
removal of the growth substrate; and
removal of the carrier substrate.

15. An opto-electronic fabrication method according to claim 14, further comprising forming a light conversion layer onto the opto-electronic matte.
